(19) United States
(12) Patent Application Publication
(10) Pub. No.: US 2026/0235704 A1
(43) Pub. Date: Aug. 13, 2026

(54) LINEARIZATION OF MAGNETIC SENSOR OUTPUT BASED ON CONTINUOUS CORRECTION OF HIGH ORDER VOLTAGE OUTPUT COMPONENTS

(71) Applicant: ALLEGRO MICROSYSTEMS, LLC, Manchester, NH (US)

(72) Inventors: Santiago SERRANO GUISAN, San Jose, CA (US); Hakan ATES GURCAN, Los Gatos, CA (US); Ali ALAOUI, Polienas (FR); Anuraag MOHAN, Fremont, CA (US)

(73) Assignee: ALLEGRO MICROSYSTEMS, LLC, Manchester, NH (US)

(21) Appl. No.: 18/260,151

(22) PCT Filed: Nov. 19, 2021
(86) PCT No.: PCT/IB2021/060743

§ 371 Date: Jun. 30, 2023

Related U.S. Application Data
(60) Provisional application No. 63/132,089, filed on Dec. 30, 2020.

(51) Int. Cl. G01R 33/00; G01D 3/02; G01R 33/09

(52) U.S. Cl. CPC G01R 33/0029; G01D 3/022; G01R 33/098

(57) ABSTRACT

A correction method for correcting an output signal provided by a magnetoresistive sensor in the presence of an external magnetic field, includes: determining a deviation of the output signal from a linear response by an amplitude of a high order component signal of the output voltage; and determining a corrected output signal by compensating the output signal for the high order component signal such that the corrected output signal varies linearly with a variation of the external magnetic field within a variation range. Further, an integrated circuit (IC) can be configured to perform the method and a characterization method to derive common parameters used when performing the correction method, for a plurality of magnetoresistive sensors.

### CROSS-REFERENCE TO RELATED APPLICATIONS

This application is a national phase of PCT/IB2021/060743 filed on Nov. 19, 2021, which claims the priority of U.S. Provisional Application No. 63/132,089, filed on Dec. 30, 2020. The entire contents of these applications are hereby incorporated by reference in their entireties.

### TECHNICAL DOMAIN

The present disclosure concerns a correction method for correcting an output voltage signal provided by a tunnel magnetoresistive sensor in the presence of an external magnetic field and an integrated circuit (IC) configured to perform the method. The present disclosure further pertains to a characterization method to derive common parameters used when performing the correction method, for a plurality of magnetoresistive sensors.

### RELATED ART

Linear magnetic sensors have many consumer, industrial and automotive applications. Current sensing, positioning, proximity detection, biometric sensing are some examples. Sensor technologies using Magnetic Tunnel Junctions (MTJs) based on Tunnel Magneto-Resistance (TMR) effect (thereafter called TMR sensor) excel among rival technologies based on Anisotropic Magneto-Resistance (AMR) effect, Giant Magneto-Resistance (GMR) effect and Hall effect, thanks to their higher sensitivity and Signal-to-Noise Ratio (SNR), lower temperature dependence, better long-term stability and generally smaller die size.

A TMR sensor can comprise one or a plurality of magnetoresistive elements, each magnetoresistive element comprising an MTJ. MTJs are connected in various series and parallel combinations to satisfy specific application requirements such as bandwidth, power consumption and noise. Commonly, such TMR sensors are configured in a Wheatstone bridge arrangement and provide an output voltage (Vₒᵤₜ) that is roughly proportional to external applied magnetic field. However, the larger the magnetic field is, the larger is the deviation of Vₒᵤₜ from a perfect linear response.

The linearity of such magnetoresistive sensor sensors can generally be improved by the development of novel magnetic stacks enabling larger working magnetic field ranges. However, the improvement in linearity usually comes at the expense of a reduction of sensor sensitivity.

The typical response of a TMR sensor under an external magnetic field (H), Vₒᵤₜ can be approximated by the equation:

$${V}_{out} = {a}_{0} + {a}_{1} \cdot H - {a}_{3} \cdot {H}^{3} \qquad ( Eq . 1 )$$

Where a₀ is the sensor offset, a₁, and a₃ are the coefficients for linear and 3^{rd} order components, respectively. Usually, a₁>>a₃, which implies that even higher order components (5^{th}, 7^{th}, 9^{th}, . . . ) are negligible and will not be considered here. The approximation given in Eq.1 is based on measurements of many TMR sensors with different magnetic stacks, and was found to reflect the behavior of the sensors accurately for the purposes of this disclosure.

FIG. 1 shows the linearity error derived from a linear TMR sensor for different magnetic field ranges. When Vₒᵤₜ is fitted to a linear function, linearity error increases rapidly with the considered magnetic field range (see dashed lines in FIG. 1) reaching values >1% for magnetic field ranges >40 mT. This rapid increase of linearity error, due to the presence of additional high order components on Vₒᵤₜ, limits the working magnetic field range of such sensors. The ratio between the third order coefficient and the linear coefficient (a₃/a₁) will therefore determine the linearity error of the sensor at a fixed magnetic field range or the working field range to obtain a linearity error below a certain value (see FIGS. 2a and 2b). In FIG. 1, black dots show the linearity error derived by considering a Vₒᵤₜ^{~}c₀+c₁·H (Linear Fit) while open dots show the linearity error derived by considering a Vₒᵤₜ^{~}a₀+a₁·H−a₃·H₃.

FIG. 2a shows simulation of linearity error vs a₃/a₁ ratio for a magnetic field range of 100 mT, and FIG. 2b shows the maximum magnetic field range in order to have a linearity error <0.5% vs a₃/a₁ ratio.

Although commercial linear TMR sensors usually work up to 40 mT, there are several applications where either high accuracy linear response might be required (<0.1%) (like precise positioning for surgical or aerospace applications), or larger magnetic fields (up to 100 mT) might be involved.

Thus, development of MTJ stack ensuring a high linear Vₒᵤₜ response can improve the linearity of the sensor, but at the expense of sensor sensitivity. Lookup table-based solutions or solutions based on calculation of a correction polynomial, which require ADCs, DACs, memory, and a microcontroller and which involve full digital reconstruction of V_{corr}, leading to high power consumption, lower speed and large die area.

### SUMMARY

In order to develop a highly-linear TMR sensor, two different strategies can be considered. One is to develop a different magnetic stack configuration. Another is to develop correction strategies to reduce linearity error of an output voltage of the TMR sensor. Each strategy has its advantages and disadvantages as summarized in Table 1.

In this disclosure, methods for correcting an output voltage and improve the linearity of a TMR sensor without reduction of sensitivity are discussed. Several approaches are proposed to approximately determine and then compensate for high order terms of the output voltage which are the main source of non-linearity of the output voltage response.

TABLE 1
Comparison of two principal non-linearity correction approaches

| | advantages | disadvantages |
|---|---|---|
| Magnetic stack | increase of working magnetic field range | Reduction of sensitivity |
| development | simple architecture | |
| | low noise | |
| | low power consumption | |
| | fast response | |
| | no calibration required | |
| ASIC | increase of working magnetic field range | increase in power consumption |
| development | no reduction in sensitivity | impact on speed |
| | large improvement on linearity | potential increase of noise |
| | potentiality to be implemented in all linear | potential calibration required |
| | TMR sensors | increase of cost / unit |
| | | additional architecture |

The methods proposed here enable to substantially improve linearity error (so larger magnetic field ranges can be achieved) with no loss in sensitivity. Moreover, the correction methods have the potential to be implemented in every linear magnetoresistive sensor substantially improving the linearity error of currently existing devices.

It is a goal of the correction methods presented here to achieve a stable output voltage response which is relatively insensitive to sample-to-sample, temperature and operating voltage variations. This implies that such corrections can be achieved by applying the same parameter set for all devices on a wafer, avoiding time consuming individual calibration procedures for each sensor device that might impact manufacturing cost and reliability performance.

In particular, the present disclosure concerns a correction method for correcting an output signal provided by a magnetoresistive sensor in the presence of an external magnetic field, comprising: determining a deviation of the output signal from a linear response by an amplitude of a high order component signal of the output signal; and determining a corrected output signal by compensating the output signal for the high order component signal such that the corrected output signal has a linearity error smaller than 2%, preferably smaller than 1%, more preferably smaller than 0.5%, for a magnetic field range up to 100 mT.

The present disclosure further concerns an IC configured to perform the method and a characterization method to derive common parameters used when performing the correction method, for a plurality of magnetoresistive sensors.

### SHORT DESCRIPTION OF THE DRAWINGS

Exemplar embodiments of the invention are disclosed in the description and illustrated by the drawings in which:

FIG. 1 shows uncorrected linearity error and linearity error after third order non-linearity correction;

FIGS. 2a and 2b show simulation of linearity error vs first order coefficient/third order coefficient ratio (a1/a3) for a magnetic field range of 100 mT (FIG. 2a) and maximum magnetic field range vs a1/a3 in order to have a linearity error <0.5% (FIG. 2b);

FIGS. 3a to 3d show potential implementations of a first correction method, where FIG. 3a shows an example of ASIC circuitry for linearity correction, FIG. 3b shows a comparison of magnetic field dependence of raw output voltage of sensor and corrected output voltage, FIG. 3c shows a comparison of linearity error, and FIG. 3d illustrates an alternative ASIC circuitry for linearity correction;

FIG. 4 shows an implementation circuit of piece-wise linear correction without discontinuities;

FIG. 5 shows the piecewise linear non-linearity correction method and circuit with 3-segments, according to an embodiment;

FIGS. 6a and 6b report the reduction of the non-linearity of an magnetoresistive sensor using a 3-segment piecewise linear correction method, showing the sensor non-linearity with and without correction (FIG. 6a) and the sensor output voltage with and without correction (FIG. 6b);

FIG. 7 shows non-linearity correction of four different magnetoresistive sensors from the same wafer using the same circuit parameters;

FIG. 8 shows the piecewise linear non-linearity correction method and circuit with 5-segments, according to an embodiment;

FIGS. 9a and 9b report the reduction of the non-linearity of an actual sensor using a 5-segment piecewise linear correction method, showing the sensor non-linearity with and without correction (FIG. 9a) and the sensor output voltage with and without correction (FIG. 9b);

FIG. 10 shows non-linearity correction of four different magnetoresistive sensors from the same wafer, using the same circuit parameters;

FIG. 11 shows the stability of the non-linearity correction across −50° C. to 150° C. temperature and 4.5V to 5.5V supply voltage ranges in a ratiometric system;

FIG. 12 shows a simplified preferred embodiment of the piecewise linear non-linearity correction method and circuit with 3-segments;

FIG. 13 report 3-segment simplified piecewise linear non-linearity correction of an actual sensor, showing non-linearity (FIG. 13a) and output voltage (FIG. 13b) as a function of external applied field;

FIG. 14 shows the 3-segment simplified piecewise linear non-linearity correction for four different magnetoresistive sensors on same wafer;

FIG. 15 shows shifts of the non-linearity correction with temperature and with supply voltage;

FIGS. 16a to 16d report the voltage response as a function of magnetic field of a linear magnetoresistive sensor, where FIG. 6a shows a linear fit of output voltage, FIG. 16b shows linearity error magnetic field, FIG. 16c shows a comparison between output voltage before and after correction for two different correction parameters, and FIG. 6d shows linearity error of output voltage after correction for two different correction parameters;

FIG. 17 shows a performance of linearity error based on the “Linear-Fit” linearity error correction scheme;

FIGS. 18a to 18c show validation of such linearity error correction on a linear TMR sensor, where FIG. 18a shows the raw output voltage as a function of magnetic field, FIG. 18b shows linearity error as a function of magnetic field for a linear MTJ sensor, and FIG. 18c shows linearity error considering the output voltage fitted by a third order polynomial function and linearity error after output voltage correction by “Linear-Fit” correction scheme;

FIG. 19 shows a possible embodiment of “Linear Fit” Linearity error correction using 4-quadrant multipliers, where correction is based on Eq.110 and Eq.107b;

FIG. 20 shows another embodiment of “Linear Fit” Linearity error correction using 1-quadrant multipliers, where correction is based on Eq.110 and Eq.107b;

FIG. 21 shows another embodiment of “Linear Fit” Linearity error correction using 1-quadrant multipliers, where correction is based on Eq.110 and & Eq.107b;

FIGS. 22a and 22b show an analog IC units based of a combination of LOG RATIO, LOG & ANTILOG operational amplifiers (FIG. 22a) and an analog IC unit as an Analog Multipurpose Unit (AMU);

FIGS. 23a and 23b show an output voltage and corrected output voltage of an MTJ based sensor (FIG. 23a) using an AMU and a “Linear Fit” linearity error correction scheme (FIG. 23b);

FIG. 24 shows an IC according to an embodiment;

FIG. 25 reports linearity error derived from a linear TMR sensor after linearity error correction implemented by an IC of FIG. 24 as a function of one of the input voltages of the IC;

FIG. 26 shows a full analog MTJ sensor and ASIC system, according to an embodiment;

FIG. 27 shows a full analog MTJ sensor and ASIC system, according to another embodiment;

FIGS. 28a to 28c show a diagram for digital implementation of Linearity error correction (FIG. 28a), simulation of a “Linear Fit” Linearity correction with a 12 bit and 8 bit ADC for an MTJ sensor submitted to a magnetic field up to 67 mT (FIG. 28b) and Linearity error versus number of bits of ADC (FIG. 18c);

FIG. 29 shows a flow chart of characterization and implementation of linearity error correction for the sensor devices in a wafer, according to an embodiment; and

FIG. A1 compares the output voltage obtained by Equation 103a and using an approximation of Equation 103a.

### EXAMPLES OF EMBODIMENTS

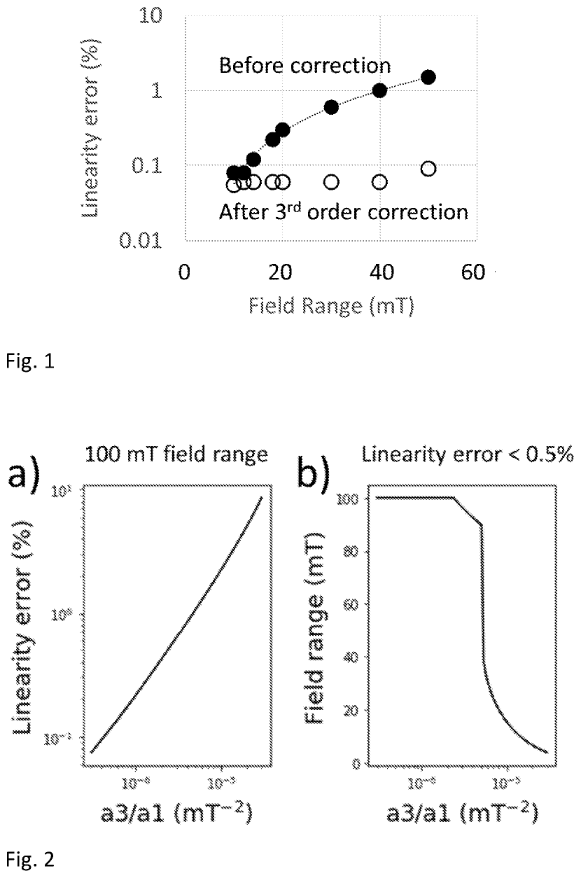

The voltage response of a linear TMR sensor can be described by Eq. 1 and rewritten as:

$${V}_{out} = {a}_{0} + {a}_{1} \cdot H + {V}_{ho} \qquad ( Eq . 2 a )$$

$$with :$$

$${V}_{ho} = {a}_{3} \cdot {H}^{3} - {a}_{5} \cdot {H}^{5} \qquad ( Eq . 2 b )$$

where Vₕₒ is a high order component voltage, showing the contribution to the output voltage Vₒᵤₜ from all non-linear components. Coefficients a₁, a₃ and as are the coefficients for linear, 3rd and 5th order components, respectively. The deviation of Vₒᵤₜ from a perfect linear response (so called “linearity error” or “non-linearity”) is determined by the amplitude of Vₕₒ, which rapidly increases with applied magnetic field which, in turn, causes an increase in linearity error (see FIG. 1).

The proposed non-linearity correction methods explained below rely on the compensation of high order components of Vₒᵤₜ. In other words, a corrected output voltage V_{corr} is determined by compensating the output voltage Vₒᵤₜ for the high order component voltage Vₕₒ such that the corrected output voltage V_{corr} varies linearly with a variation of the external magnetic field (H) within a larger magnetic field range. This compensation can be done in a piecewise linear or continuous manner.

This compensation method may be implemented in hardware (analog), software (digital) or hybrid hardware and software (analog and digital) circuit.

### First Correction Method: Piece-Wise Linear Correction

The first correction method to be described is a piece-wise linear correction method. To illustrate this approach, the output voltage Vₒᵤₜ of the sensor is divided into non-overlapping output voltage segments V_{out,i}. The method can be extended to as many output voltage segments as practical. In this description, first a three-segment case is considered for simplicity:

$$output voltage segment I ( {V}_{out , 1} ) for {V}_{out} < V 1$$

$$output voltage segment II ( {V}_{out , 2} ) for {V}_{out} > V 2 ; and$$

$$output voltage segment III ( {V}_{out , 3} ) for V 1 \leq {V}_{out} \leq V 2 ,$$

wherein each segment transition thresholds V1 and V2 segments the output voltage segments V_{out,1}, V_{out,2} and V_{out,3}, and where V1<V2.

Within each output voltage segment V_{out,i} is approximated by a linear equation:

$${V}_{out , i} ∼ {d}_{0 i} + {d}_{1 i} \cdot H \qquad ( Eq . 100 )$$

where i is an index referring to output voltage segment I, II or III and where d₀ᵢ and d₁ᵢ is, respectively, the sensor offset and the coefficient for linear component, of the output voltage segment. From Eq. 100, H can be written as:

$$H ∼ ( {V}_{out i} - {d}_{0 i} ) / {d}_{1 i} \qquad ( Eq . 101 )$$

Knowing by previous characterization of the sensor the actual a₀ and a₁ coefficients (Eq. 2a), the corrected voltage output V_{corr, i} in each output voltage segment V_{out,i} can be written as:

$${V}_{corr , i} = {a}_{0} + {a}_{1} \cdot ( ( {V}_{out i} - {d}_{0 i} ) / {d}_{1 i} ) = {A}_{i} + {B}_{i} \cdot {V}_{out i} - \qquad ( Eq . 102 a )$$

$$with$$

$${A}_{i} = {a}_{0} - ( {d}_{0 i} / {d}_{1 i} ) ; and {B}_{i} = ( {a}_{1} / {d}_{1 i} ) \qquad ( Eq . 102 b )$$

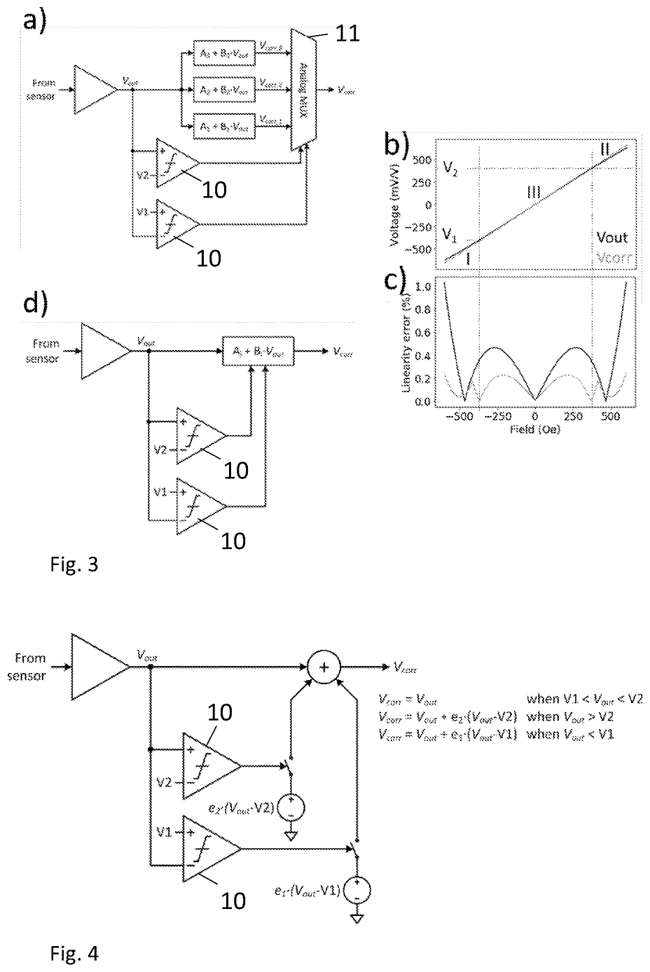

FIGS. 3a to 3d show potential high level implementations of the first correction method. Such simple correction enables reduction of linearity error by four to five times (see FIG. 3c).

FIG. 3a shows an example of circuitry for Linearity correction based on Eqs.102a, 102b. In FIG. 3a, the circuit comprises at least two comparators 10 where each comparator is inputted by the output signal Vₒᵤₜ and one of the segment transition threshold Vᵢ. FIG. 3b shows a comparison of magnetic field dependence of output voltage of sensor Vₒᵤₜ and corrected output voltage V_{corr} considering such linearity correction scheme. In this example a₀=1 mV/V, a₁=1.1 mV/V/mT and a₃=1.5·10⁻⁵ mV/V/mT³. FIG. 3c shows a comparison of linearity error of Vₒᵤₜ and V_{corr}. FIG. 3d illustrates an alternative ASIC circuitry for Linearity correction based on Eqs. 102a, 102b.

In the example of FIG. 3a, a pair of comparators determines the output voltage segment V_{out,i} of operation based on segment transition thresholds V1 and V2, and accordingly routes the corresponding corrected signal V_{corr,i} to the output. The correction functions (Aᵢ+Bᵢ*Vₒᵤₜ) can easily be implemented by common analog circuitry such as operational amplifiers and passive components. The example of FIG. 3d is an alternative implementation where the comparators are used to select a pair of Aᵢ, Bᵢ coefficients based on the output voltage segment V_{out,i} of operation. This concept, exemplified in a 3-segment scenario, can naturally be extended into more numerous output voltage segments V_{out,i}, which would allow more accurate correction of sensor non-linearity. It should be noted that the circuitry shown in FIG. 3a can comprise only one comparator 10 (for example, when only one half of the sensor output is utilized, such as in unipolar applications).

A particularly useful implementation of Equation 102a is shown in the circuit of FIG. 4 and considers the following: for small values of Vₒᵤₜ, no correction is needed, then A₃=0 and B₃=1, thus V_{corr,3}=V_{out,3}. The circuit of FIG. 4 can comprise only one comparator 10.

The corrected output voltage V_{corr} must not have discontinuities at segment transitions as discontinuities are highly undesirable in application. V1 and V2 being the segment transition voltages, this can be achieved by maintaining a relationship between Bᵢ and Aᵢ as given below, i.e., B₁=1+e₁, A₁=−e₁·V1 and, B₂=1+e₂, A₂=−e₂·V2.

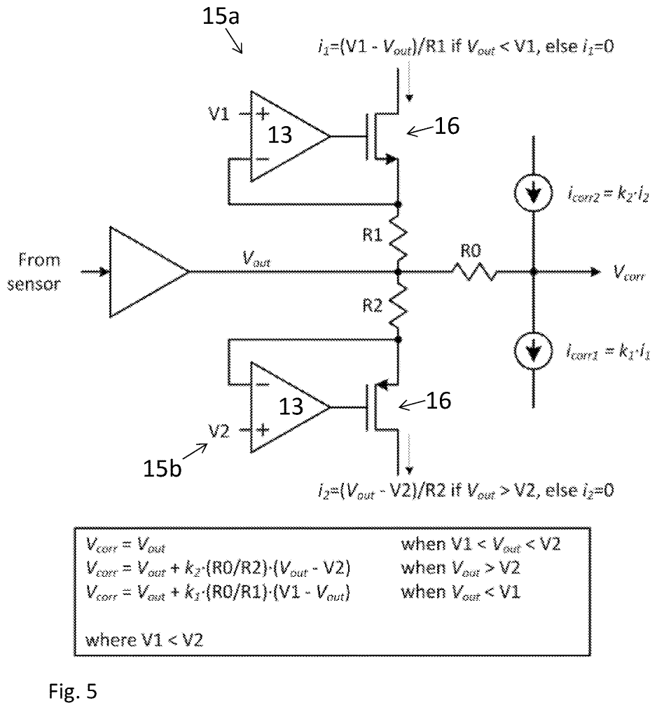

A preferred embodiment of the piecewise linear correction method shown in FIG. 4 includes traditional circuit elements such as Operational Amplifiers, transistors and resistors as shown in the circuit of FIG. 5. In this preferred embodiment, the functions of the comparators and voltage sources of FIG. 4 are combined in the voltage-to-current (V-to-I) converters composed of operational amplifiers, MOS transistors and resistors. The summing operation is performed in current domain, by means of current mirrors whose output currents are applied to R₀, generating the corrected output voltage V_{corr}. The segment transition threshold voltages V1 and V2, as well as R1 and R2 are preferably implemented as programmable parameters which can be modified based on the characteristics of the sensor, to optimize the non-linearity correction. The circuit is configured to output the output signal segment V_{out,i} when the output signal segment V_{out,i} is greater than the segment transition threshold Vᵢ, and output the corrected output signal segment V_{corr,i} added to the output signal segment V_{out,i} when the output signal segment V_{out,i} is greater than the segment transition threshold Vᵢ.

Continuing with FIG. 5, in one aspect, a first voltage-to-current converter circuit 15a can comprise a first resistor R₁ and be configured to generate a first current i₁ as a function of a difference between the voltage signal V_{out,i} and the threshold signal Vᵢ. A second voltage-to-current converter circuit 15b can comprise a second resistor R₂ and be configured to generate a second current i₂ as a function the first current i₁. A correction resistor R₀ generates the corrected output signal segment V_{corr,i} when second current i₂ is supplied to the correction resistor R₀. The circuit is configured to output the output signal segment V_{out,i} when the latter is smaller than the segment transition threshold Vᵢ and output the corrected output signal segment V_{corr,i} added to the output signal segment V_{out,i} when the latter is greater than the segment transition threshold Vᵢ. The first current i₁ can be generated as a linear function of a difference between the output signal segment V_{out,i} and segment transition threshold Vᵢ. The circuit of FIG. 5 can comprise only one voltage-to-current converter circuit (such as 15b) for unipolar applications.

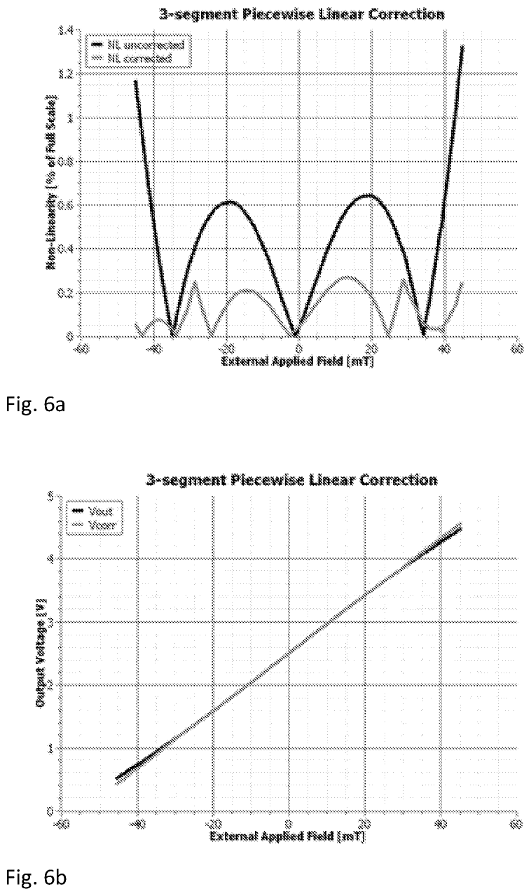

FIGS. 6a and 6b show the reduction of the non-linearity of an actual magnetoresistive sensor using the 3-segment piecewise linear correction method within the magnetic field range of −45 mT to +45 mT. FIG. 6a shows the sensor non-linearity with and without correction. FIG. 6b shows the sensor output voltage with and without correction. As it can be observed in the plots, an approximately five times reduction in non-linearity is achieved with the 3-segment piecewise linear correction method (from ^{~}1.3% down to ^{~}0.25% of full-scale). For this case, the following circuit parameters were used: V1=1.2 V, V2=3.8 V, R₀=15 kΩ, R1=R2=120 kΩ and k₁=k₂=1.

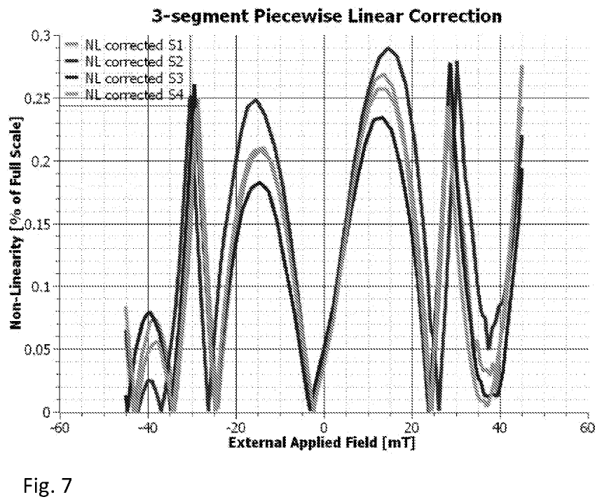

Typically, magnetoresistive sensors coming from the same wafer exhibit similar non-linearity characteristics. Thus, the correction circuit parameters can be determined once per wafer and applied to all sensor dice on the same wafer. FIG. 7 shows non-linearity correction of four different sensors from the same wafer, using the same circuit parameters. As it would be observed on the plots, the non-linearity cancellation is effective for all sensors presented. In FIG. 7, the 3-segment non-linearity correction of the four magnetoresistive sensors from the same wafer used the same circuit parameter set as in FIG. 6 (V1=1.2 V, V2=3.8 V, R0=15 kΩ, R1=R2=120 kΩ, k1=k2=1).

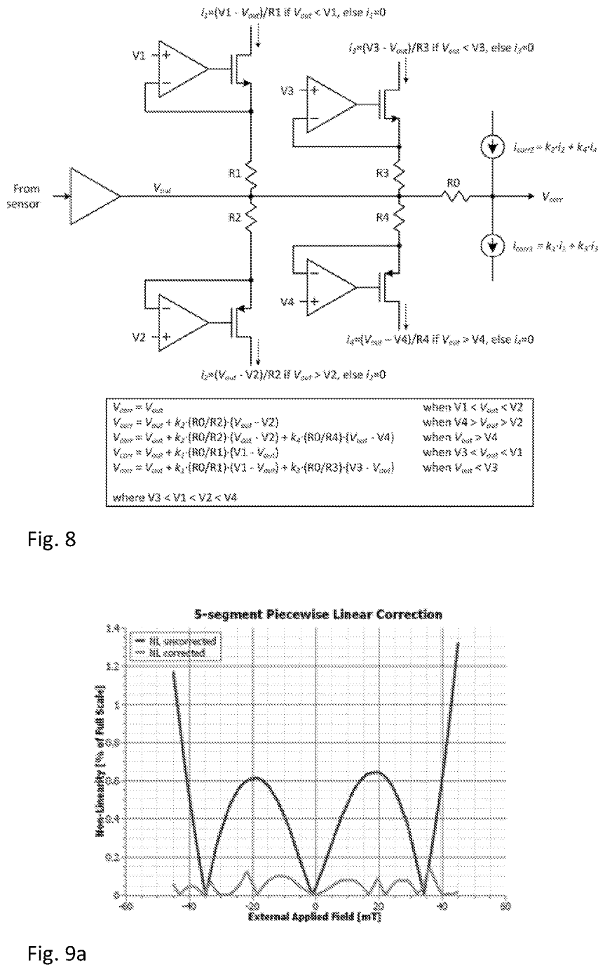

The piecewise linear non-linearity correction method shown in FIG. 4 can easily be augmented to higher number of output voltage segments for achieving higher levels of non-linearity correction. FIG. 8 shows a preferred embodiment with 5-segments.

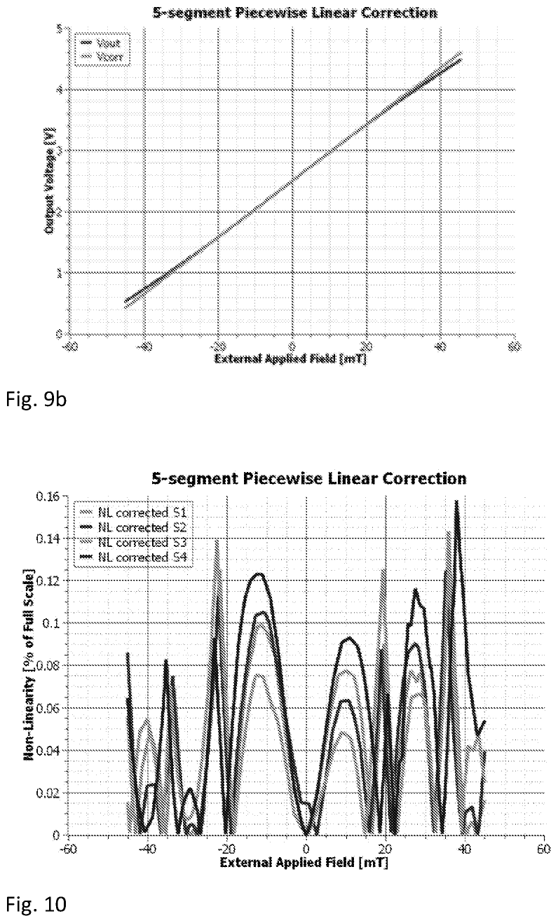

FIGS. 9a and 9b show the reduction of the non-linearity of an actual magnetoresistive sensor using the 5-segment piecewise linear correction method within the magnetic field range of −45 mT to +45 mT. FIG. 9a shows the sensor non-linearity with and without correction. FIG. 9b shows the sensor output voltage with and without correction. As it can be observed in the plots, an approximately nine times reduction in non-linearity is achieved with the 5-segment piecewise linear correction method (from ^{~}1.3% down to ^{~}0.14% of full-scale). For this case, the following circuit parameters were used: V1=1.5V, V2=3.4V, V3=1.0V, V4=4.1V, R0=15 kΩ, R1=R2=200 kΩ, R3=225 kΩ, R4=150 kΩ, k₁=k₂=k₃=k₄=1.

Note that the sensor considered in FIG. 9 and FIG. 8 is the same sensor considered in FIG. 6.

FIG. 10 shows non-linearity correction of four different magnetoresistive sensors from the same wafer, using the same circuit parameters. As it would be observed on the plots, the non-linearity cancellation is effective for all sensors presented. In FIG. 10, the 5-segment non-linearity correction used the same circuit parameter set (V1=1.5V, V2=3.4V, V3=1.0V, V4=4.1V, R0=15 kΩ, R1=R2=200 kΩ, R3=225 kΩ, R4=150 kΩ, k₁=k₂=k₃=k₄=1) as in FIGS. 9a, 9b.

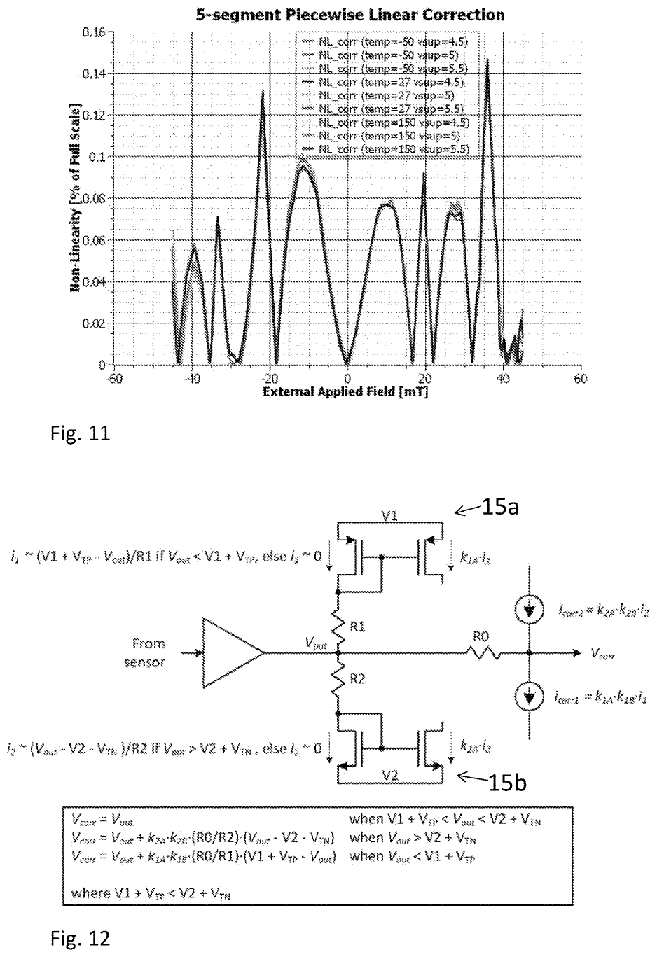

The embodiments shown in FIG. 5 and FIG. 8 offer non-linearity correction which remains stable across temperature and supply voltage ranges (assuming the sensor's inherent non-linearity characteristics remain unchanged over the temperature and voltage ranges). FIG. 11 shows the stability of the non-linearity correction (5-segment considered) across−50° C. to 150° C. temperature and 4.5V to 5.5V supply voltage ranges in a ratiometric system. Please note that in a ratiometric system, the segment threshold voltages V1, V2, V3 and V4 need also be ratiometrically changing with the supply voltage, which is easily implemented by means of a voltage divider. In a non-ratiometric system, the segment threshold voltages V1, V2, V3 and V4 need to be temperature independent constant voltage levels, which could be generated by a temperature insensitive voltage reference.

In FIG. 11, the 5-segment non-linearity correction stability over −50° C. to 150° C. temperature and 4.5V to 5.5V supply voltage ranges in a ratiometric system used the parameters: V1=1.5V, V2=3.4V, V3=1.0V, V4=4.1V, R0=15 kΩ, R1=R2=200 kΩ, R3=225 kΩ, R4=150 kΩ, k₁=k₂=k₃=k₄=1. Note: threshold voltages V1, V2, V3, V4 are given for 5V and change ratiometrically with VDD).

In the preferred embodiments of FIG. 5 and FIG. 8, to enable continuous real-time non-linearity correction, the voltage-to-current converters should preferably be designed to have high slew rate and wider bandwidth than the main signal chain with a large enough phase margin to avoid overshoots. However, their gain and input offset requirements are not necessarily stringent thus can be designed with relative ease.

Another and simpler preferred embodiment of the piecewise linear correction method shown in FIG. 4 includes traditional circuit elements such as transistors and resistors as shown in FIG. 12. FIG. 12 shows a simplified embodiment of the piecewise linear non-linearity correction method with 3-segments. In this preferred embodiment, the functions of the comparators and voltage sources of FIG. 4 are combined in the simplified voltage-to-current (V-to-I) converters composed of MOS transistors and resistors (each voltage-to-current converter circuit 15a, 15b may comprise a MOS transistor). The summing operation is performed in current domain, by means of current mirrors whose output currents are applied to R0, generating the corrected output voltage, V_{corr}.

The preferred embodiment shown in FIG. 12 uses resistors and transistors arranged in current mirror configuration, to generate currents which are proportional to Vₒᵤₜ, in Vₒᵤₜ ranges determined by bias voltages V1 and V2 and PMOS/NMOS transistor threshold voltages V_{TP} and V_{TN} respectively. Although FIG. 12 shows simple current mirrors based on MOS transistors, the same functionality can be achieved using bipolar junction transistors (BJT), and by different current mirror arrangements.

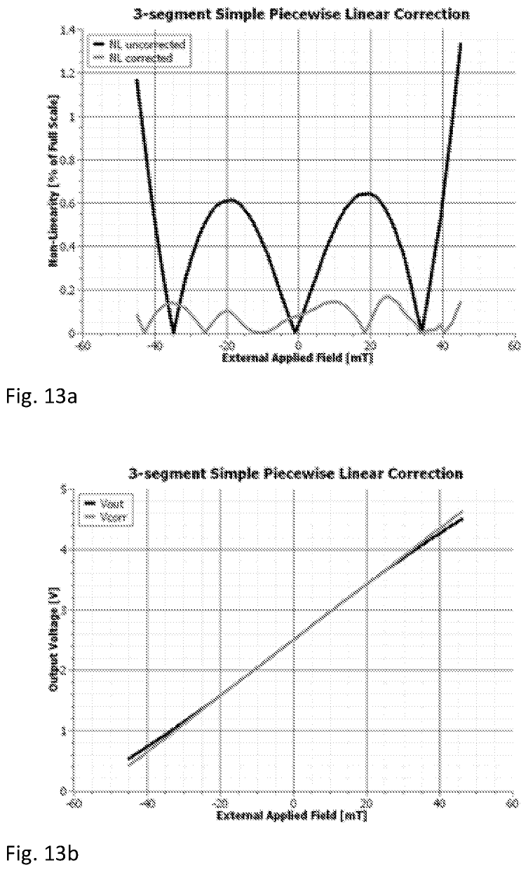

For simplicity, the equations listed in FIG. 12 suggest that i₁ and i₂ start flowing at exact Vₒᵤₜ levels of (V1+VTP) and (V2+VTN) respectively, however, the turning on of the MOS transistor is gradual in nature. This behavior of the MOS transistors has the advantage of smoothing out the transitions between output voltage segments. On the other hand, the dependence of the segment threshold voltages on MOS transistor thresholds make the correction dependent on process, temperature, and supply variations. Furthermore, in this simplified embodiment, a true ratiometric correction cannot be established. Still, a significant degree of linearity improvement can be achieved by this simple circuitry. The circuitry shown in FIG. 12 in a 3-segment arrangement can naturally be extended to more numerous output voltage segments, allowing higher levels of non-linearity correction. FIGS. 13a and 13b report 3-segment simplified piecewise linear correction applied to an actual magnetoresistive sensor with the following circuit parameters: V1=3.1 V, V2=2.2 V, R0=15 kΩ, R1=R2=70 kΩ, k_{1A}=k_{1B}=k_{2A}=k_{2B}=1, showing non-linearity (FIG. 13a) and Vₒᵤₜ (FIG. 13b) as a function of external applied field.

Like previous embodiments, the same correction circuit parameter set as in FIGS. 13a, 13b (V1=3.1 V, V2=2.2 V, R0=15 kΩ, R1=R2=70 kΩ, k_{1A}=k_{1B}=k_{2A}=k_{2B}=1) can be used for all magnetoresistive sensors coming from the same wafer. FIG. 14 shows four different sensors non-linearity corrected with the same parameter set.

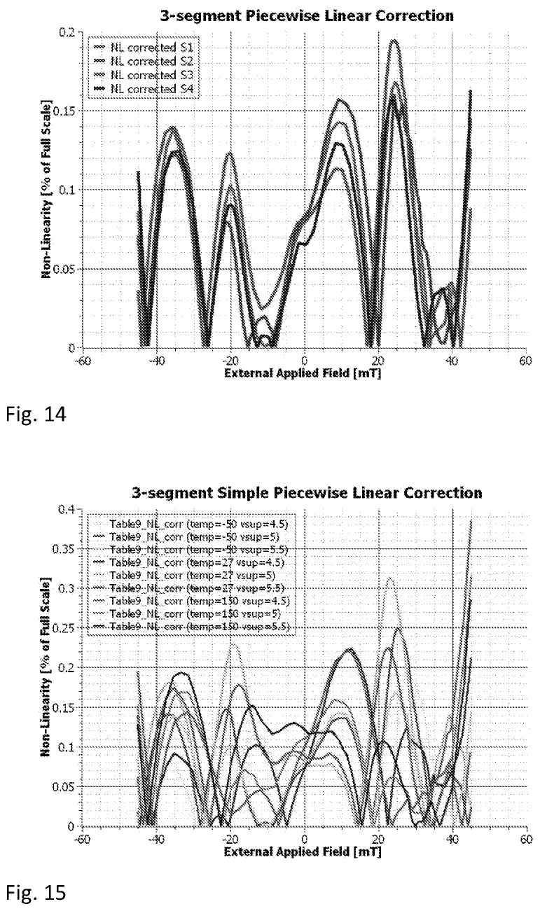

The shifts of the non-linearity correction with temperature (due to shifts in MOS transistor characteristics) and with supply voltage (due to the lack of true ratiometry) are shown in FIG. 15. Note that the maximum non-linearity after correction, which was optimized to remain <0.2% of full scale at 27° C., 5V, nearly doubles in the −50° C. to 150° C. temperature and 4.5V to 5.5V supply voltage range. This is in contrast with the embodiments described earlier, which remained nearly unchanged across the same temperature and voltage ranges. In FIG. 15, the 3-segment simple non-linearity correction stability over −50° C. to 150° C. temperature and 4.5V to 5.5V supply voltage ranges in a ratiometric system used parameter set: V1=3.1V, V2=2.2V, R0=15 kΩ, R1=R2=70 kΩ, k_{1A}=k_{1B}=k_{2A}=k_{2B}=1. Note: V1 and V2 are given for 5V and change ratiometrically with V_{DD}.

### Second Correction Method: Linear-Fit Correction

Another possible method relies on the determination of an additional voltage signal V_{sub} from the output signal Vₒᵤₜ and close enough to −Vₕₒ (in other words corresponding to a negative value of the high order component signal Vₕₒ). Thus, by adding V_{sub} to Vₒᵤₜ a very linear corrected output voltage V_{corr} can be derived. In other words, a corrected output signal V_{corr} can be determined by compensating the output signal Vₒᵤₜ for the high order component signal Vₕₒ by adding the additional signal V_{sub} (derived from the output signal Vₒᵤₜ) to the output signal Vₒᵤₜ. For instance, if we consider that Vₒᵤₜ can be described by Eq. 1, and a₁>a₃ and a₅^{~}0 (which is usually the case) then:

$${V}_{out} = {a}_{0} + {a}_{1} \cdot H - {a}_{3} \cdot {H}^{3} \qquad ( Eq . 103 a )$$

Therefore, V_{sub} needs to be as close as possible to a₃·H³ so:

$${V}_{corr} = {V}_{out} + {V}_{sub} = {a}_{0} + {a}_{1} \cdot H - {a}_{3} \cdot {H}^{3} + {V}_{sub} ∼ {a}_{0} + {a}_{1} \cdot H \qquad ( Eq . 103 b )$$

In order to achieve this, it is essential, again, to “estimate” as accurately as possible the measured magnetic field H. Note that determining H by solving the third order equation Eq. 103a will adversely impact sensor's time response and power consumption. The idea behind this correction method is to use an approximate solution to the measured field H so V_{sub} is close enough to a₃·H³ and therefore a large reduction of linearity error can be achieved while minimizing power consumption and impact on sensor's time response. Using the approximation (1−ax)≈1/(1+ax) for ax<<1, we can approximate Eq.103a to:

$${V}_{o u t} ∼ \frac{{a}_{1} \cdot H}{1 + ( {a}_{3} / {a}_{1} ) \cdot {H}^{2}} \qquad ( Eq . 104 )$$

Note that in this case sensor offset term a₀ has been omitted for sake of clarity. Therefore, Eq. 104 can be considered as an approximate description of the magnetic field dependence of magnetoresistive sensor's Vₒᵤₜ. Note that this approximation implies that a much simpler analytical solution for H than just deriving the solution from Eq.103a can be found. Consequently, a V_{sub} derived from Vₒᵤₜ could be determined and linearity error can be largely reduced. The solution to Eq. 104 can be approximated to (see Annex for full analysis):

$${H}_{0} ∼ \frac{{a}_{1}^{2}}{4 {a}_{1} {V}_{o u t}} D \cdot [ 1 + ( \frac{D}{4} ) + ( \frac{{D}^{2}}{8} ) ] = \frac{{V}_{o u t}}{{a}_{1}} \cdot [ 1 + ( \frac{D}{4} ) + ( \frac{{D}^{2}}{8} ) ] \qquad ( Eq . 105 a )$$

$$with$$

$$D = 4 ( {a}_{3} {V}_{o u t}^{2} / {a}_{1}^{3} ) \qquad ( Eq . 105 b )$$

This implies that V_{sub} could be described as:

$${V}_{s u b} = {a}_{3} {H}_{0}^{3} \qquad ( Eq . 106 a )$$

And the corrected output voltage V_{corr} can be described as:

$${V}_{c o r r} = {V}_{o u t} + {V}_{s u b} = {V}_{o u t} + {a}_{3} {H}_{0}^{3} \qquad ( Eq . 106 b )$$

This correction method can be slightly generalized by considering:

$${V}_{corr} = {V}_{out} + k \cdot {H}_{0}^{3} \qquad ( Eq . 107 a )$$

$$with$$

$$k = C \cdot {a}_{3} and 0.5 < C < 4. \qquad ( Eq . 107 b )$$

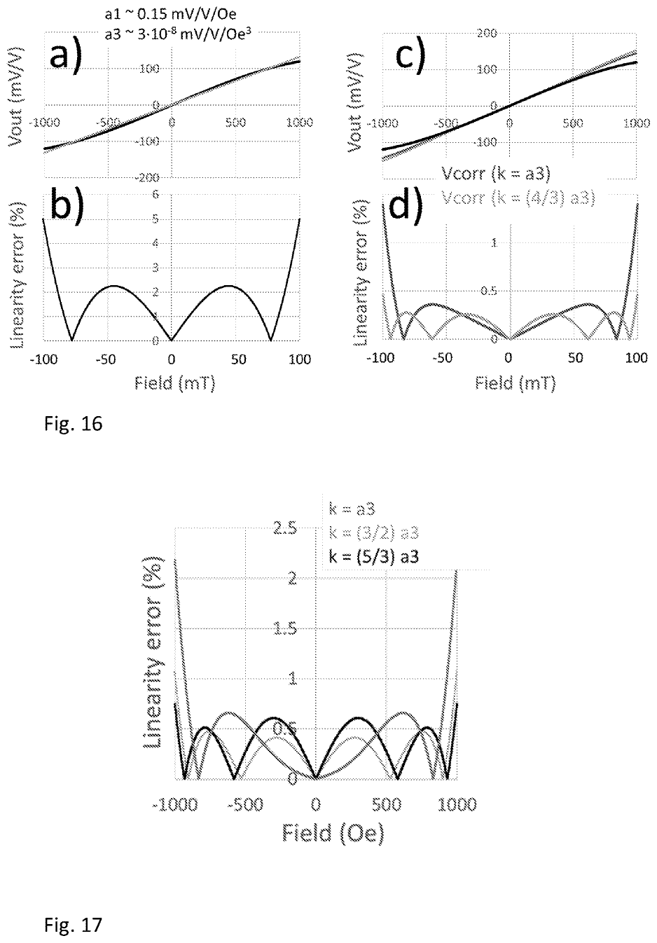

Note that FIGS. 16a to 16d shows the performance of this correction method.

FIG. 16a shows voltage response as a function of magnetic field of a linear magnetoresistive sensor with a linear coefficient a₁^{~}1.5 mV/V/mT and 3^{rd} order coefficient a₃^{~}3.10⁻⁵ mV/V/mT³. Grey line shows the linear fit (LinFit) of Vₒᵤₜ. FIG. 16b shows linearity error (defined as 100×ABS [LinFit−Vout]/[VoutMax−VoutMin]) as a function of magnetic field. The error induced when considering Vₒᵤₜ as a perfect linear function is as high as 5%. Note that even for small magnetic fields (<20 mT), Vₒᵤₜ shows a linearity error >1% (see FIG. 16b) FIGS. 16c and 16d: show the performance of correction scheme based on Eq. 105 and Eq.107. FIG. 16c shows the comparison between Vₒᵤₜ (black curve) and Vₒᵤₜ after correction (V_{corr}) for two different values of parameter k (dark and light grey curves). Such scheme enables to reduce Linearity error to values <0.5% (so a reduction of ×10). Note that in both V_{corr} signals the sensitivity is about 1.5 mV/V/mT which is the same as the linear coefficient (a₁) of Vₒᵤₜ. These results confirm the potential of such correction scheme as no loss of sensitivity is obtained. FIG. 16d shows linearity error of both V_{corr} (for two different values of parameter k).

Determination of V_{sub} by Eq.105 and Eq.107 may require however large amount of computation power. In order to overcome this problem lower order solutions to Eq.105a can be considered too:

$${H}_{-} ∼ \frac{{a}_{1}^{2}}{4 {a}_{1} {V}_{out}} D \cdot [ 1 + ( \frac{D}{4} ) ] = \frac{{V}_{out}}{{a}_{1}} \cdot [ 1 + ( \frac{D}{4} ) ] \qquad ( Eq . 108 a )$$

$${H}_{-} ∼ \frac{{a}_{1}^{2}}{4 {a}_{1} {V}_{out}} D = \frac{{V}_{out}}{{a}_{1}} \qquad ( Eq . 108 b )$$

Nevertheless, the smaller is the order solution considered the larger will be the mismatch between H₀ and the measured field H leading to a larger linearity error. An optimum compromise between low computation requirement and high linearity error correction can be obtained when considering:

$${H}_{0} = \frac{{V}_{out}}{{c}_{1}} \qquad ( Eq . 109 )$$

where c₁ refers to the linear coefficient determined by a linear fitting of raw Vₒᵤₜ. This implies that:

$${V}_{corr} = {V}_{out} + k \cdot {( \frac{{V}_{out}}{{c}_{1}} )}^{3} . \qquad ( Eq . 110 )$$

Indeed, by considering Eq. 110 and 107b as a correction scheme, a linearity error of the V_{corr}<0.5% for magnetic fields up to 94 mT can be obtained (see FIG. 17). This linearity error correction approach will be called as “Linear Fit” linearity correction.

In one aspect, the additional signal V_{sub} to be added to the output signal Vₒᵤₜ to derive the corrected signal V_{corr} is proportional to the power three of the output signal Vₒᵤₜ (Vₒᵤₜ³).

In one aspect, the additional signal V_{sub} further comprises additional terms proportional to higher order components than the third order component of the output voltage signal Vₒᵤₜ, such that:

$${V}_{sub} = {\sum }_{j = 1}^{N} {α}_{2 j + 1} \cdot {V}_{out}^{2 j + 1} . \qquad ( Eq . 110 a )$$

In another aspect, the additional signal V_{sub} can further be defined by:

$${V}_{sub} = k \cdot {( \frac{{V}_{out}}{{c}_{1}} )}^{3} , where k = C \cdot {a}_{3} , \qquad ( Eq . 110 b )$$

with 0.5<C<4, and wherein c₁ is a linear coefficient determined by a linear fitting of the output signal (Vₒᵤₜ) with respect to the applied magnetic field H, and a₃ is the third order coefficient of the output voltage.

In another aspect, the additional signal V_{sub} can be further defined by:

$${V}_{sub} = k \cdot {( \frac{{V}_{out}}{{a}_{1}} \cdot [ 1 + ( D / 4 ) ] )}^{3} , \qquad ( Eq . 110 c )$$

where

$$D = 4 ( {a}_{3} {V}_{out}^{2} / {a}_{1}^{3} )$$

and k=C·a₃, with 0.5<C<4, and wherein a₁ and a₃ are the linear and third order coefficient of the output signal Vₒᵤₜ, respectively.

In another aspect, the additional signal V_{sub} can be further defined by:

$${V}_{sub} = k \cdot {( \frac{{V}_{out}}{{a}_{1}} \cdot [ 1 + ( D / 4 ) + ( {D}^{2} / 8 ) ] )}^{3} , \qquad ( Eq . 110 d )$$

where

$$D = 4 ( {a}_{3} {V}_{out}^{2} / {a}_{1}^{3} )$$

and k=C·a₃, with 0.5<C<4, and wherein a₁ and a₃ are the linear and third order coefficient of the output signal Vₒᵤₜ, respectively.

FIG. 17 shows the performance of “Linear Fit” linearity error correction scheme (by considering Eq. 110 and 107b) when k=a₃ (dark grey curve), k=(3/2) a₃ (light grey curve) and k=(5/3) a₃ (black curve) for a linear MTJ sensor with a linear coefficient a₁^{~}1.55 mV/V/mT and 3rd order coefficient a₃^{~}3·10⁻⁵ mV/V/mT³.

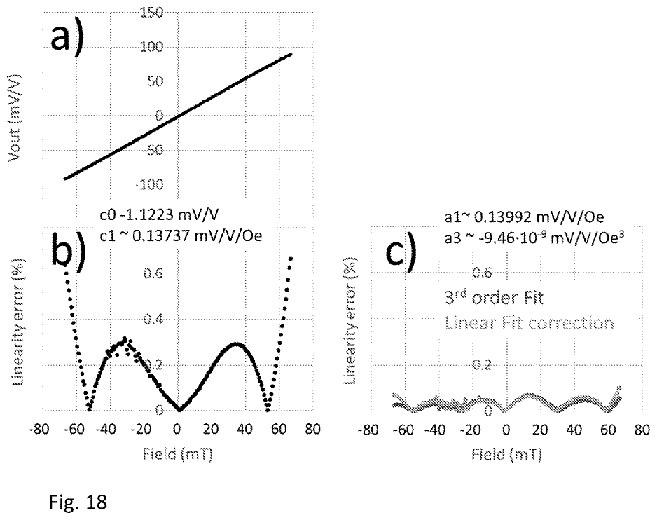

FIGS. 18a to 18c show validation of such “Linear Fit” linearity error correction approach on a different linear TMR sensor. FIG. 18 show Vₒᵤₜ and its linearity error as a function of magnetic field for fields up to 67 mT. In this case Vₒᵤₜ^{~}c₀+c₁ H, with c₀^{~}1.122 mV/V and c₁ ^{~}1.37 mV/V/mT and linearity error ^{~}0.7%. FIG. 18c shows that if Vₒᵤₜ is fitted by a 3rd order polynomial function as Eq. 103a), the fitting error between Vₒᵤₜ and the fitting function decreases to values ^{~}0.1%. The profile of this fitting error vs magnetic field (light grey curve in FIG. 18c) is a signature of the contribution of the 5^{th} order component of Vₒᵤₜ. Note, however, that if “Linear Fit” correction used, linearity error of V_{corr} is also ^{~}0.1% with a similar magnetic field dependence (see dark grey curve in FIG. 18c). This result shows that 3^{rd} order component of Vₒᵤₜ is completely compensated by “Linear Fit” correction.

For this TMR sensor, an initial linearity error of 0.7% is obtained for magnetic fields up to 67 mT (see FIG. 18b). The linear coefficients derived from such linear fit are c₀^{~}1.122 mV/V and c₁^{~}1.37 mV/V/mT. However, by considering the linearity correction scheme from Eq. 109 and Eq. 107 linearity error drops down to 0.09% (see dark grey curve in FIG. 18c).

Moreover, this “Linear Fit” linearity correction is very robust against typical parameter variability from device to device. Table 2 summarizes the result of eight magnetoresistive sensors submitted to magnetic fields up to 47 mT. Initial linearity error is ^{~}1.35% for all of them and after “Linear Fit” correction, Linearity error drops to ^{~}0.15%. Note that this improvement on linearity error (about nine times) is obtained despite the initial dispersion of c₁ and a₃ parameters (~10%) from device to device and by using the same c₁ and a₃ coefficients for correction.

TABLE 2

| | | | | | | | Corrected |
|---|---|---|---|---|---|---|---|
| | | | | | | Linearity | Linearity |
| Sample | c0(mV/V) | c1(mV/V/mT) | a0(mV/V) | a1(mV/V/mT) | a3(mV/V/mT³) | Error (%) | Error (%) |
| d02 | 0.19110 | 3.53046 | 0.16152 | 3.67473 | 1.08E.04 | 1.345 | 0.082 |
| d03 | 1.47345 | 3.67531 | 1.44050 | 3.82190 | 1.10E.04 | 1.357 | 0.171 |
| d04 | 1.50776 | 3.73569 | 1.50576 | 3.89732 | 1.21E.04 | 1.452 | 0.12 |
| d05 | 0.47689 | 3.56869 | 0.47115 | 3.71859 | 1.13E.04 | 1.336 | 0.064 |
| d07 | −0.99734 | 3.37359 | −1.00287 | 3.51151 | 1.04E.04 | 1.255 | 0.151 |
| d08 | 1.84584 | 3.47688 | 1.81742 | 3.61661 | 1.05E.04 | 1.336 | 0.065 |
| d09 | −0.20777 | 3.70629 | −0.19998 | 3.86673 | 1.20E.04 | 1.406 | 0.098 |
| d10 | −2.23640 | 3.50801 | −2.23564 | 3.64957 | 1.06E.04 | 1.299 | 0.03 |

In Table 2, “Linear Fit” linearity error correction in eight different linear TMR sensors when submitted to magnetic fields up to 47 mT. Coefficients c₀ and c₁ refer to coefficients obtained by linear fit of Vₒᵤₜ, i.e., Vₒᵤₜ=c₀+c₁ H. Coefficients a₀, a₁ and a₃ are obtained by fitting Vₒᵤₜ^{~}a₀+a₁·H−a₃·H³. Initial linearity error (derived from linear fit of Vₒᵤₜ)^{~}1.35% for all devices. By considering the median of c1 & a3 coefficients of all devices (c_{1_median}=3.54893 mV/V/mT and a_{3_median}=1.09E⁻⁴ mV/V/mT³) in Eq.109 and Eq.107 a corrected voltage output V_{corr} is obtained. Linearity error of V_{corr} (Corrected Linearity Error)^{~}0.15% for all devices.

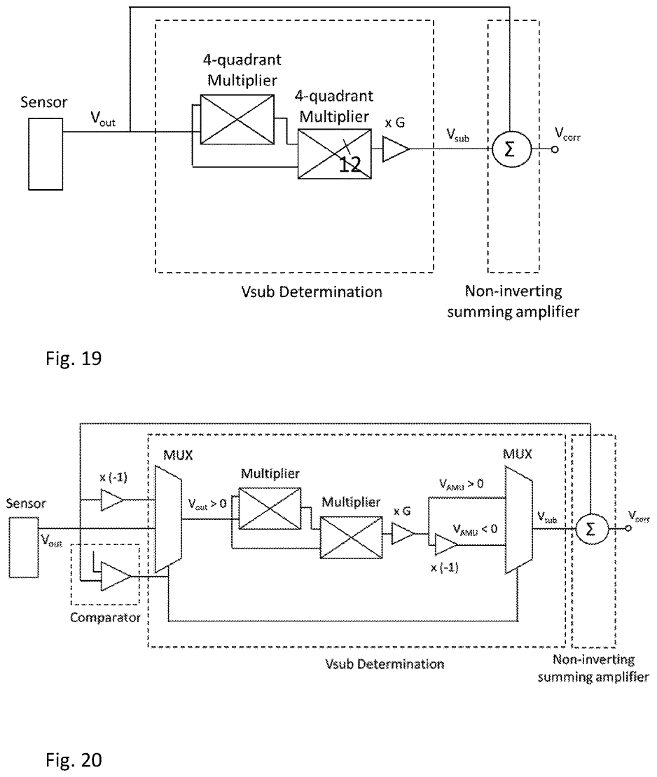

FIG. 19 illustrates an embodiment of a “Linear Fit” linearity correction implementation. The IC comprises two cascaded voltage multipliers 12. We consider a multiplier 12 as an analog IC unit made of a combination of several LOG and ANTILOG operational amplifiers where its signal output V_{MULT} is the product of two input signals V1 and V₂, so V_{MULT}=V₁·V₂. The combination of two multipliers 12 in cascade enables the determination of a signal^{~}Vₒᵤₜ³, which is the main component of V_{sub}. In this embodiment multipliers 12 are able to operate at any possible polarity of V₁ and V₂ (4-quadrant multipliers). The circuit also comprises an operational amplifier 13 with gain G=k/c₁³. Note that if V_{MULT}=β·V₁·V₂ (being β a parameter intrinsic of the voltage multiplier) then the operational amplifier 13 should have a gain G=(k/c₁³)·(1β^{B2}). Then by a non-inverting summing amplifier both Vₒᵤₜ and V_{sub} signals are added leading to a corrected output signal V_{corr}=Vₒᵤₜ+(k/c₁³)·Vₒᵤₜ³. Note that the same embodiment shown in FIG. 19 comprising 1-quadrant multipliers can be used for unipolar applications, i.e. in case that linearity error correction is only required at one specific polarity of Vₒᵤₜ.

In case multipliers can only operate at one specific polarity of V₁ and V₂ (1-quadrant multipliers) and linearity correction at both polarities of Vₒᵤₜ is required an alternative embodiment is illustrated in FIG. 20. Without any loss of generality this specific embodiment shows multipliers 12 working only for V>0 In this embodiment, the IC comprises two multipliers 12, an operational amplifier 13 with gain G=k/c₁³, two inverting amplifiers 14, a comparator 10 as well as multiplexers 11 (MUX) and/or demultiplexers 11 (DMUX). The role of the comparator, the inverting amplifiers and the MUXs and/or DMUXs is to enable voltage multipliers 12 operate at both polarities of the output voltage Vₒᵤₜ and ensure the determination of V_{sub} for either polarity of Vₒᵤₜ. The comparator 10 inputted by the output signal Vₒᵤₜ triggers both MUXs 11 so depending on the comparator output value, MUXs will select one of its two input signals. Therefore, it is possible to configure the first MUX so its output signal is always positive enabling the operation of at least two cascaded multipliers to compute a signal~Vₒᵤₜ³. After amplification of this signal by operational amplifier 13 a signal V_{sub}=(k/c₁³)·Vₒᵤₜ³>0 is obtained. After inverting polarity of V_{sub} with inverting amplifier 14, the second MUX will select the right polarity of V_{sub}.). Then by a non-inverting summing amplifier both Vₒᵤₜ and V_{sub} signals are added leading to a corrected output signal V_{corr}=Vₒᵤₜ+ (k/c₁³). Vₒᵤₜ³. Note that in this specific embodiment two MUXs were considered, but without any loss of generality two DMUXs could be used instead or any combination of both MUX and DMUX.

Note that adding additional multipliers in such cascade structure will enable to correct other high order contributions of Vₒᵤₜ (5^{th}, 7^{th}, . . . ).

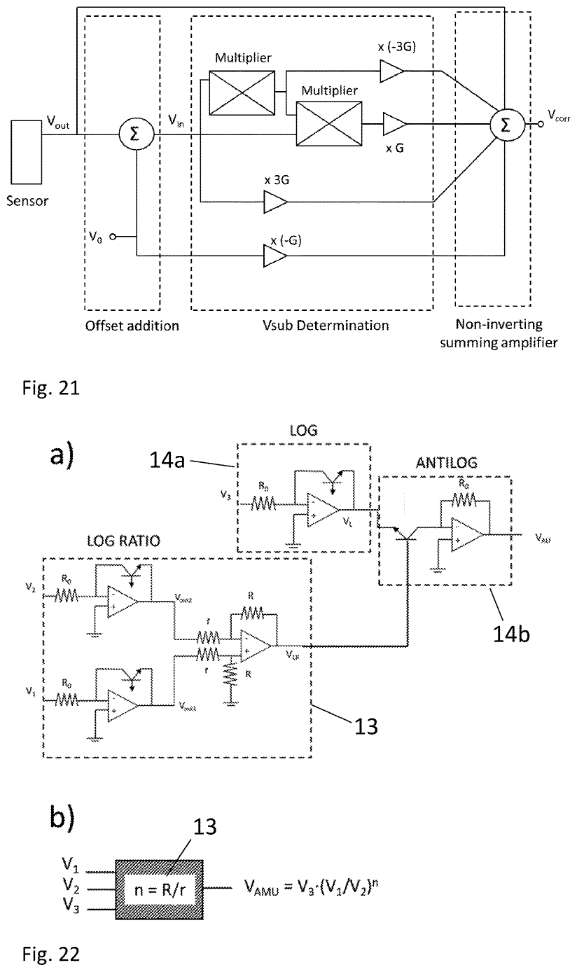

Another embodiment for linearity correction at both polarities of Vₒᵤₜ concerning 1-quadrant multipliers is sketched in FIG. 21. Here, a voltage signal offset V₀ is added to the output voltage signal Vₒᵤₜ and an input voltage Vᵢₙ corresponding to the sum of the voltage signal offset V₀ and the output voltage signal Vₒᵤₜ is inputted to said two cascaded voltage multipliers 12). The idea behind this case is that a voltage offset (V₀) is added to the output voltage Vₒᵤₜ before determination of V_{sub} so the input voltage Vᵢₙ=V₀+Vₒᵤₜ>0 for all magnetic fields. Note that because only a constant voltage is added to Vₒᵤₜ the same correction method can still be applied. In this case, however Eq. 110 becomes:

$${V}_{corr} = {V}_{out} + k \cdot {( \frac{{V}_{in} - {V}_{0}}{{c}_{1}} )}^{3} = {V}_{out} + ( \frac{k}{{c}_{1}^{3}} ) \cdot ( {V}_{in}^{3} - 3 \cdot {V}_{in}^{2} \cdot {V}_{0} + 3 \cdot {V}_{in} \cdot {V}_{0}^{2} - {V}_{0}^{3} ) . \qquad ( Eq . 111 )$$

This configuration enables to remove the comparator as well as MUXs and DMUXs considered in the previous embodiment of FIG. 20. Note that if we want to keep the same number of multipliers involved as in FIG. 20 then, and according to Eq. 111, V₀, V₀² & V₀³ need to be three different reference voltages. However, a special case of this embodiment is when V₀=1V (and therefore V₀=V₀²=V₀³), as shown in FIG. 21. Note also that for this case, some additional voltage amplifiers are required with gains G, −G, 3G & −3G (where G=k/c₁³).

Note that in all previous embodiments, adding additional multipliers in such cascade structure will enable to correct other high order contributions of Vₒᵤₜ (5^{th}, 7^{th}, . . . ).

In all previous embodiments, cascaded multipliers were used to obtain a V_{sub}^{~}Vₒᵤₜ³ However, other analog IC units can also be considered for this purpose. Some analog IC units based of a combination of LOG RATIO, LOG & ANTILOG operational amplifiers as sketched in FIG. 22a can perform the following operation:

$${V}_{out , AMU} = {V}_{in , 3} \cdot {( {V}_{in , 1} / {V}_{in , 2} )}^{n} \qquad ( Eq . 112 )$$

where V_{in,1}, V_{in,2} and V_{in,3} are three input signals, n is a parameter depending on the ratio between the two different resistors in the circuit and V_{out,AMU} is the output signal of the IC unit

Considering the different type of operations it can potentially perform (multiplication, division, power and roots) we define this analog IC unit as an Analog Multipurpose Unit (or AMU) and is sketched in FIG. 22b. When considering the input signals V_{in,1}=Vₒᵤₜ, V_{in,3}/V_{in,2}³=k/c₁³ and n=3, then the output signal of AMU (V_{AMU}) can be expressed as:

$${V}_{out , AMU} = k \cdot {( \frac{{V}_{out}}{{c}_{1}} )}^{3} \qquad ( Eq . 113 )$$

Thus V_{out,AMU} can be added to the output signal of the sensor Vₒᵤₜ to obtain the linearized corrected output signal V_{corr}=Vₒᵤₜ+ (k/c₁³)·Vₒᵤₜ³.

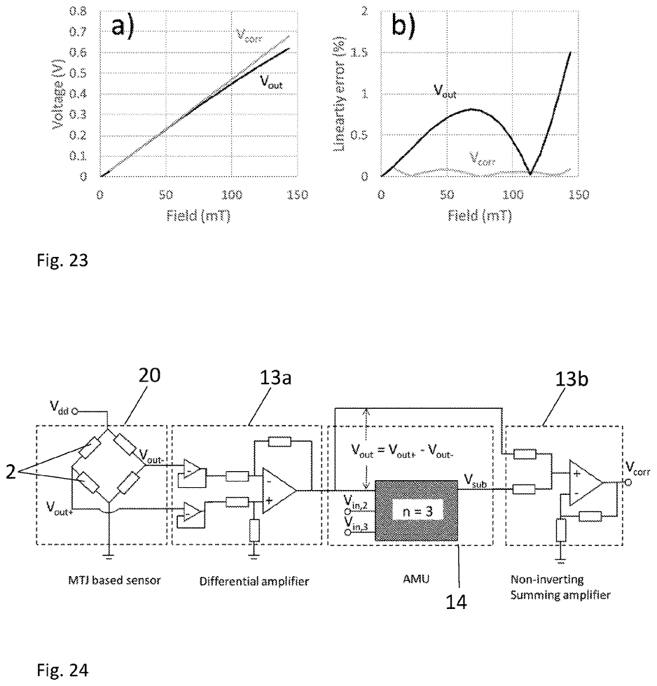

FIG. 23a shows the output voltage Vₒᵤₜ and corrected output voltage V_{corr} of an MTJ based sensor when exposed to magnetic fields from 0 mT to 140 mT V_{corr} is obtained by an AMU considering the embodiment of FIG. 24. For this particular case V_{in,1}=Vₒᵤₜ, V_{in,2}=V_{in,3}=2V and V_{dd}=3V. FIG. 23b shows that by this correction scheme linearity error drops from ~1.5% to 0.12%. Note that for this sensor c₁^{~}1.45 mV/V/mT and a₃^{~}5.97.106 mV/V/mT³. leading to a a₃/c₁^{3~}0.2156 V⁻² which is very close to the value obtained by V_{in,3}/V_{in,2}³=0.25 V⁻².

FIG. 24 shows an IC according to an embodiment, comprising a full bridge magnetoresistive sensor 20 including four magnetoresistive elements 2, a differential amplifier 13a, an AMU 14, and a non-inverting summing amplifier 13b.

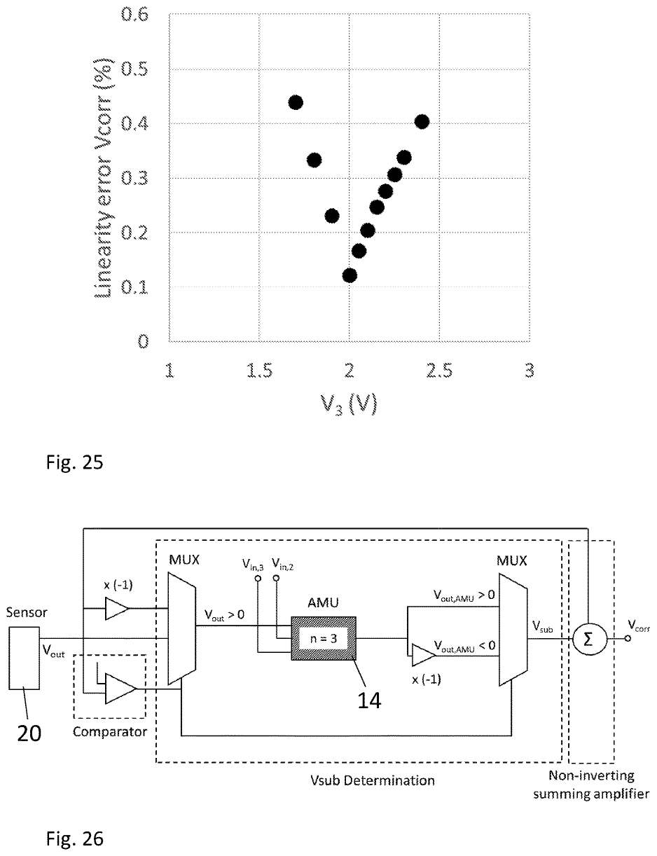

Moreover, FIG. 25 reports linearity error derived from a linear TMR sensor and an IC described by FIG. 24 as a function of the input voltage V_{in,3}. FIG. 25 shows that by fine tuning V_{in,3} between 1.7 V and 2.4V we can still obtain linearity errors below 0.45%. As V_{in,3}/V_{in,2}³=k/c₁³, this result shows robustness of this scheme against possible variations of c₁ and a₃ coefficients of the TMR sensor.

All these results show the feasibility of implementing this linearization correction scheme in a full analog MTJ sensor+ASIC system based, at least, on: a MTJ based magnetic sensor showing an output voltage Vₒᵤₜ dependent on the external magnetic field (Eq. 103), an AMU configured in such a way that its output voltage V_{out,AMU} is proportional to Vₒᵤₜ³ (and described by Eq. 113) and a voltage summing amplifier so its output voltage is V_{corr}=Vₒᵤₜ+V_{out, AMU}=Vₒᵤₜ+k· (Vₒᵤₜ/c₁)³.

Note that, in case of using a 1-quadrant AMU, embodiment of FIG. 24 only works for one polarity of Vₒᵤₜ and therefore for just one direction of the magnetic field. Several other embodiments (FIG. 26, 27) can then be considered to implement this linearization correction scheme for positive and magnetic field amplitudes. For this, two options (similar to the ones previously described in FIG. 20 & FIG. 21) can be considered.

For example, in one embodiment a full analog MTJ sensor+ASIC system (see FIG. 26) is comprised of: an MTJ based magnetic field sensor, a comparator (to determine the polarity of sensor's output voltage Vₒᵤₜ), two inverters (one to invert polarity of Vₒᵤₜ and another one to invert polarity of V_{out,AMU}), an AMU enabling to compute V_{out,AMU}^{~}Vₒᵤₜ³, couple of MUXs and/or DMUXs in order to select the right Vₒᵤₜ and V_{AMU} signal to determine V_{sub} and a voltage summing amplifier so its output voltage is V_{corr}=Vₒᵤₜ+V_{out,AMU}=Vₒᵤₜ+k. (Vₒᵤₜ/c₁)³.

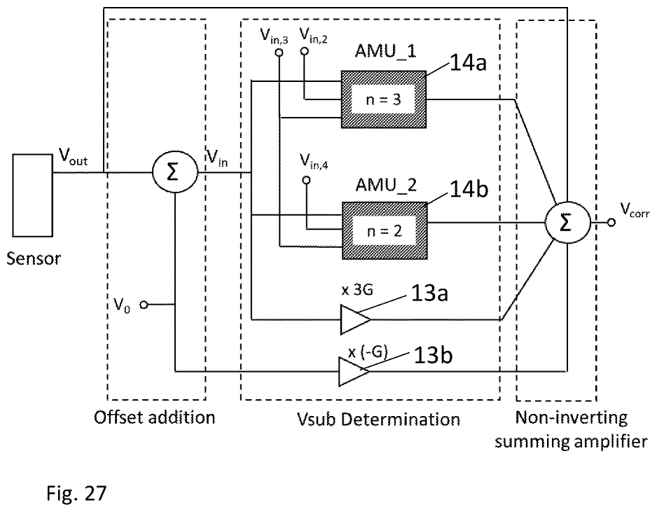

In another embodiment, a full analog MTJ sensor+ASIC system (FIG. 27) is comprised of: a magnetoresistive sensor, a reference offset voltage V₀ that is added to Vₒᵤₜ so Vᵢₙ=V₀+Vₒᵤₜ>0 for all magnetic fields, a first AMU 14a enable to compute Vᵢₙ³, a second AMU 14b (or another analog IC circuit) enable to compute Vᵢₙ², a first voltage amplifier 13a enabling to amplify Vᵢₙ by a factor×3G (where G=k/c₁³), a second voltage amplifier 13b enabling to amplify V₀ by a factor x (−G) and a voltage summing amplifier so V_{corr} can be determined by Eq. 111. In this embodiment, the sum of the offset signal V₀ and the output signal Vₒᵤₜ is inputted into said at least one AMU 14a, 14b and into the first voltage amplifier 13a. The corrected output signal V_{corr} is the sum of the output voltage of the AMUs 14a, 14b plus the output voltage of the first and second voltage amplifiers 13a, 13b. Note that a special case of this embodiment is when V₀=1V (and therefore V₀=V₀²=V₀³), as shown inf FIG. 27.

Note that in all above mentioned embodiments higher order correction terms (5^{th}, 7^{th}, . . . ) can also be implemented by adding additional AMUs with n=5, 7 . . . .

In one aspect, the additional signal V_{sub} can further comprise additional terms proportional to higher order components than the third order component of the output signal Vₒᵤₜ, such that:

$${V}_{sub} = {\sum }_{j = 1}^{N} {α}_{2 j + 1} \cdot {V}_{out}^{2 j + 1} \qquad ( Eq . 114 )$$

Different approaches can also be considered depending on the initial a₃/a1 ratio and summarized in Table 3, however for the majority of analog implementations only the first approach (“Linear Fit”) is relevant, as the other approaches (like “2D Fit” or “3D Fit”) might imply more complex analog IC systems. In particular, Table 3 reports conditions for a₁ and a₃ coefficients to obtain a V_{corr} with a Linearity error<0.5% for a magnetic field range up to 100 mT.

TABLE 3

| Correction | H. | k | a₃/a₁ (100 mT field range) |
|---|---|---|---|
| Linear Fit | Vout/c1 | C · a3 | ≤ 1.7.10⁻⁷ |
| 2D Fit | $\frac{{V}_{out}}{{a}_{1}} \cdot [ 1 + ( \frac{D}{4} ) ]$ | C · a3 | ≤ 1.75.10⁻⁷ |
| 3D Fit | $\frac{{V}_{out}}{{a}_{1}} \cdot [ 1 + ( \frac{D}{4} ) + ( \frac{{D}^{2}}{8} ) ]$ | C · a3 | ≤ 2.0.10⁻⁷ |

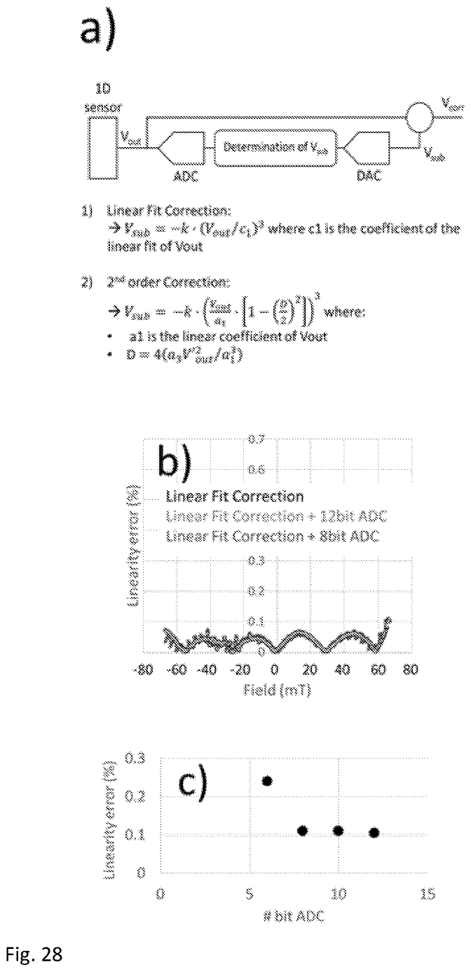

Nevertheless, “2D Fit” or “3D Fit” correction methods can also be considered when a digital analysis of V_{sub} is considered. FIGS. 28a to 28c illustrate an approach where V_{sub} is basically determined digitally and then by a DAC this signal can be subtracted from the raw Vₒᵤₜ, so a pure analog V_{corr} signal is obtained. In this case, the main characteristics of the correction method would be based (as sketched in FIG. 28a by: 1) an Analog-to-Digital converter (ADC), 2) a Digital System (DS) to determine V_{sub}, and 3) a Digital-to-Analog converter (DAC). Note that such a DS can be composed of a microcontroller (MCU), a look-up table (LUT) or any other kind of combination of microprocessors, memory units and MCUs.

FIG. 28a shows a Diagram of an embodiment for Digital implementation of Linearity error correction. Vₒᵤₜ is converted to a digital signal by an ADC. Determination of V_{sub} is made by a DS. Once V_{sub} has been digitally determined is converted to an analog signal and added to Vₒᵤₜ to obtain V_{corr}. FIG. 28b shows simulation of a “Linear Fit” Linearity correction with a 12 bit and 8 bit ADC for a magnetoresistive sensor submitted to a magnetic field up to 67 mT. FIG. 28c shows Linearity error vs number of bits of ADC.

In FIG. 28a, the ADC and the DAC are only used for the calculation of V_{sub} while subtraction from Vₒᵤₜ is made analogically. Thus, a simpler design, with lower bit counts can be made to operate faster at reasonable power consumption. Moreover, this approach has the advantage to be combined with any of both proposed analog linearization method, especially when large magnetic fields are applied, requiring again a simpler design and low bit counts. Note that unlike previously developed digital linearization approaches relying on full digital reconstruction of V_{corr} this proposed method is based on digital determination of additional signal V_{sub} and analog correction by addition of Vₒᵤₜ and V_{sub} (after digital-to-analog conversion).

Finally, in order to implement such correction method at production level is not only necessary to show its robustness against parameters variability from device to device (as shown in Table 2) but it is also essential to derive such common parameters c₁ and a₃ without full characterization of each individual device of a wafer. Once these parameters are determined then a common ASIC system that will perform the linearization correction for all devices of the same wafer can be implemented.

In an embodiment, a non-transitory computer readable medium storing a program causing a computer to execute the method

In an embodiment, a characterization method to derive common parameters for a plurality of TMR sensors wherein the common parameters are used when performing the correction method is disclosed.

In one aspect, the characterization method comprises:
providing a plurality of magnetoresistive sensors and measuring the output signal Vₒᵤₜ for each magnetoresistive sensor;
determining the offset coefficient a₀, the first order coefficient a₁, and at least a third order coefficient a₃ by fitting the measured output signal Vₒᵤₜ to Vₒᵤₜ=a₀+a₁·H−a₃·H³;
determining the approximated offset coefficient c₀ and the approximated first order coefficient c₁ by fitting the measured output signal Vₒᵤₜ to Vₒᵤₜ=c₀+c₁·H; and
determining the median values for the determined offset coefficients a₀, first order coefficients a₁, at least third order coefficients a₃, approximated offset coefficients c₀ and approximated first order coefficients c₁.

Measuring the output signal Vₒᵤₜ can be performed when submitting the magnetoresistive sensors to an external magnetic field H corresponding to maximum operational magnetic field range H₂ of the magnetoresistive sensors.

The plurality of magnetoresistive sensors can comprise a subset of magnetoresistive sensors comprised in a wafer. For example, the subset of magnetoresistive sensors can comprise between 10 and N, where N is the total number of magnetoresistive sensors on the wafer.

In one aspect, measuring an output signal Vₒᵤₜ can be performed when the magnetoresistive sensors are submitted to an external magnetic field H corresponding to at least five different magnetic field magnitudes. The external magnetic field H can be comprised between a high magnitude corresponding to a maximum operational magnetic field range H₂ of the magnetoresistive sensor, and a low amplitude field range H₁ where the output signal Vₒᵤₜ follows a linear dependence with the magnetic field H:

$${V}_{out} = {a}_{0} + {a}_{1} \cdot H , \qquad ( Eq . 114 )$$

Therefore, offset a₀ and linear coefficient a₁ can be obtained by a linear fit of Vₒᵤₜ at low field range. The third order coefficients a₃ can be derived by:

$${a}_{3} = [ ( {a}_{0} + {a}_{1} \cdot {H}_{2} ) - {V}_{out\_H2} ] / {H}_{2}^{3} \qquad ( Eq . 115 )$$

where V_{out_H2}) is the measured output voltage at the maximum operational magnetic field range H₂. Finally, after reconstruction of Vₒᵤₜ through the whole magnetic field range coefficients c₀ and c₁ are derived by the linear fit Vₒᵤₜ at maximum magnetic field range H₂.

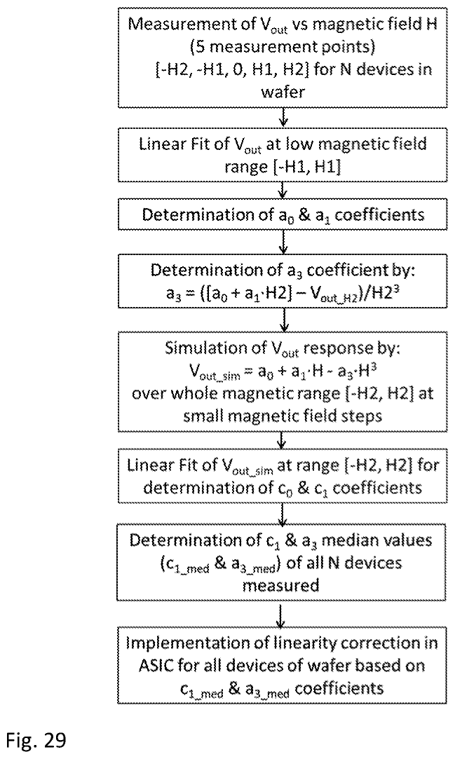

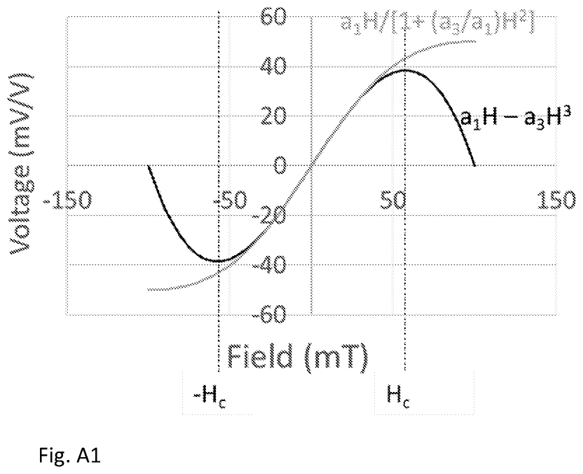

FIG. 29 shows a flow chart illustrating the characterization method that enables to obtain the common parameters by characterizing only a certain number of sensor devices N (with 10<N) of a wafer with only five magnetic field points/device. H2 is typically the maximum operational magnetic field range of the sensor and H1 is a small value of magnetic field (typically between 1-6 mT).

It should be noted that the output signal Vₒᵤₜ, high order component signal Vₕₒ, corrected output signal V_{corr}, output signal segment V_{out,i}, corrected output signal segment V_{corr,i}, additional signal V_{sub}, signal offset V₀, threshold signal Vᵢ, input signal Vᵢₙ, mentioned above can take the form of a voltage or a current.

### ANNEX A

The solution to Eq.104 can be described as:

$${H}_{0} = \frac{{a}_{1}^{2}}{2 {a}_{3} {V}_{out}} \cdot [ 1 \pm \sqrt{1 - D} ] \qquad ( Eq . A01a )$$

$$with$$

$$D = 4 ( {a}_{3} {V}_{out}^{2} / {a}_{1}^{3} ) \qquad ( Eq . A01b )$$

Moreover, the maximum magnetic field range where Vₒᵤₜ could be approximate to Eq. 103a will be delimited by the magnetic field where Vₒᵤₜ is the local max or min (see FIG. A1). This magnetic field He can be obtained by minimizing Eq.103a, so:

$${H}_{c} ∼ \pm \sqrt{\frac{{a}_{1}}{3 {a}_{3}}} \qquad ( Eq . A02 )$$

This implies that for magnetic fields from −H_{c} to H_{c}

$$D < 4 ( {a}_{3} {V}_{out max}^{2} / {a}_{1}^{3} ) ∼ 6 \qquad ( Eq . A03 )$$

Therefore, as D<1 for the interested magnetic field range, Eq. A01 can be approximate to:

$${H}_{-} ∼ \frac{{a}_{1}^{2}}{4 {a}_{3} {V}_{out}} D \cdot [ 1 + ( \frac{D}{4} ) + ( \frac{{D}^{2}}{8} ) ] = \frac{{V}_{out}}{{a}_{1}} \cdot [ 1 + ( \frac{D}{4} ) + ( \frac{{D}^{2}}{8} ) ] \qquad ( Eq . A04a )$$

$${H}_{+} ∼ \frac{{a}_{1}^{2}}{2 {a}_{3} {V}_{out}} D \cdot [ 2 - \frac{D}{2} [ 1 + ( \frac{D}{4} ) + ( \frac{{D}^{2}}{8} ) ] ] = \frac{{a}_{1}^{2}}{{a}_{3} {V}_{out}} - {H}_{-} \qquad ( Eq . A04b )$$

Note that H₊ are the solutions for magnetic fields |H|>|H_{c}|, where such approximation is not any more effective. Therefore, we will only consider H− as the possible solutions to Eq. 103b.

### Advantages of the Disclosed Technology

The correction methods presented herein can increase the working magnetic field range of a magnetoresistive sensor by improving its linearity at high fields or allow it to operate in the same magnetic field range with higher linearity, with no degradation in sensitivity.

Furthermore, the correction methods presented are suitable for real time correction of non-linearity by analog means, thus allow high bandwidth operation.

Analog non-linearity correction (first correction method with embodiments shown in, FIGS. 3, 5, 8 and 12 allows for real-time, continuous correction without a need for a microcontroller, ADC or DAC; stable over temperature and supply voltage; applicable to an entire wafer; and small footprint of the magnetoresistive sensor.

Non-linearity correction scheme based on Eq. 110 and Table 2 (second correction method, see analog implementation embodiments shown in FIGS. 19, 20, 21, 24, 26 & 27) allows for: real-time, continuous correction without a need for a microcontroller, ADC or DAC; and robustness against device-to-device parameter variations; possibility to implement this approach digitally for calculation of high order component of Vₒᵤₜ (see FIG. 29). The Non-linearity correction scheme allows for using a method for fast determination at wafer level of two main parameters of “Linear-Fit” correction method (Flow chart of FIG. 30).

The technology disclosed herein enables to: improve performance (linearity error or magnetic field range) of current linear magnetic sensors without the necessity to develop new MTJ stacks; develop new linear magnetic sensor products based on linearity error correction scheme.

The correction method described herein for correcting an output signal Vₒᵤₜ provided by a magnetoresistive sensor in the presence of an external magnetic field H allows for obtaining the corrected output signal V_{corr} having a linearity error smaller than 2%, preferably smaller than 1%, more preferably smaller than 0.5, for a magnetic field range up to 100 mT. Here the linearity error is defined as the difference between the measured output voltage signal as a function of the external magnetic field and an ideally linear relation between the output voltage signal and the external magnetic field.

### REFERENCE NUMBERS AND SYMBOLS

10 comparator
11 multiplexer, demultiplexer
12 multiplier, voltage multiplier
13 operational amplifier, voltage amplifier
13a first voltage amplifier, differential amplifier
13b second voltage amplifier, non-inverting summing amplifier
14, 14a, 14b analog Multipurpose Unit (AMU)
15a first voltage-to-current converter circuit
15b second voltage-to-current converter circuit
16 transistor
2 magnetoresistive element
20 magnetoresistive sensor
a₀ offset coefficient and
a₁ first order coefficient
a₃ third order component
c₀ approximated offset coefficient
c₁ approximated first order coefficient
H external magnetic field
H₂ maximum operational magnetic field range
i₁ first current
i₂ second current
R₀ correction resistor
R₁ first resistor
R₂ second resistor
V_{corr} corrected output voltage
Vₕₒ high order component signal
Vᵢₙ, V_{in,i} input signal
V₀ signal offset
Vₒᵤₜ output signal
V_{out,i} output signal segment
Vᵢ transition threshold signal
V_{sub} additional signal

1. A correction method for correcting an output signal provided by a magnetoresistive sensor in the presence of an external magnetic field (H), comprising:
determining a deviation of the output signal from a linear response based on an amplitude of a high order component signal of an output voltage of the magnetoresistive sensor, wherein the amplitude of the high order component signal of the output voltage is representative of contributions to the output voltage by non-linear components, wherein the amplitude of the high order component signal of the output voltage increases with an increase in an applied magnetic field to the magnetoresistive sensor; and
determining a corrected output signal by compensating the output signal for the high order component signal such that the corrected output signal has a linearity error smaller than the linearity error of the output signal, wherein compensating the output signal includes adding an additional signal derived from the output signal and based on the amplitude of the high order component signal of the output voltage.

2. The correction method according to claim 1,
wherein the output signal Vₒᵤₜ is described by:
Vₒᵤₜ=a₀+a₁·H+Vₕₒ, where His an external magnetic field, and Vₕₒ is the high order component signal, do is an offset coefficient and a₁ is a first order coefficient; and
wherein the high order component signal is described by at least a third order coefficient a₃.

3. The correction method according to claim 1,
comprising segmenting the output signal into a plurality of non-overlapping output signal segments, each output signal segment being segmented by a segment transition threshold; and
wherein each output signal segment is approximated by a linear equation to obtain a corresponding corrected output signal segment.

4. The correction method according to claim 3, wherein the corrected output signal in each output signal segment is determined by: V_{corr, i}=Aᵢ+Bᵢ·V_{out i}, where V_{corr, i} is the corrected output signal segment, V_{out I} is the output signal segment, Ai and Bi are segment coefficients.

5. The correction method according to claim 4,
wherein each output signal segment is approximated by: V_{out, i}~d₀ᵢ+d₁ᵢ·H, wherein i is an index referring to an i^{th} segment, d₀ᵢ is an offset coefficient and d₁ᵢ is a first order coefficient; and
wherein Aᵢ=a₀−(d₀ᵢ/d₁ᵢ) and Bᵢ=(a₁/d₁ᵢ).

6. The correction method according to claim 1,
wherein the additional signal is close to or equal to a negative value of the high order component signal.

7. The correction method according to claim 6, wherein the additional signal is proportional to Vₒᵤₜ³.

8. The correction method according to claim 6, wherein the additional signal further comprises additional terms proportional to higher order components than a third order component of the output signal, such that:
$${V}_{sub} = {\sum }_{j = 1}^{N} {α}_{2 j + 1} \cdot {V}_{out}^{2 j + 1} ,$$
where V_{sub} is the additional signal, α₂ⱼ₊₁ are coefficients determining a proportionality factor for each 2j+1 th order component of output signal Vₒᵤₜ.

9. The correction method according to claim 6, wherein the additional signal is defined by
$${V}_{sub} = k \cdot {H}_{0}^{3}$$
wherein H₀ is defined by:
$${H}_{0} ∼ \frac{{V}_{out}}{{a}_{1}} \cdot [ 1 + ( \frac{D}{4} ) + ( \frac{{D}^{2}}{8} ) ] ,$$
with
$$D = 4 ( {a}_{3} {V}_{out}^{2} / {a}_{1}^{3} ) , k = C \cdot {a}_{3} ,$$
with 0.5<C<4, and wherein a₁ and a₃ are the linear and third order coefficients of the output voltage, respectively, and C is a constant, so that the corrected output signal V_{corr} is defined by:
$${V}_{corr} = {V}_{out} + {V}_{sub} = {V}_{out} + k \cdot {H}_{0}^{3} .$$

10. The correction method according to claim 9,
wherein the correction method is performed using an approximation of H₀ defined by:
$${H}_{0} = \frac{{V}_{out}}{{a}_{1}} \cdot [ 1 + ( \frac{D}{4} ) ] ,$$
where
$$D = 4 ( {a}_{3} {V}_{out}^{2} / {a}_{1}^{3} )$$
and wherein a₁ and a₃ are the linear and third order coefficients of the output signal Vₒᵤₜ, respectively.

11. The correction method according to claim 6,
wherein the additional signal is defined by:
$${V}_{sub} = k \cdot {( \frac{{V}_{out}}{{c}_{1}} )}^{3} ,$$
where k=C·a₃, with 0.5<C<4, and
wherein c₁ is a linear coefficient determined by a linear fitting of the output signal with respect to the applied magnetic field H, and a₃ being the third order coefficient of the output voltage, such that the corrected output signal is defined by:
$${V}_{corr} = {V}_{out} + k \cdot {( \frac{{V}_{out}}{{c}_{1}} )}^{3} .$$

12. The correction method according to claim 8, wherein a signal offset (V₀) is added to the output signal when determining an additional signal.

13. A non-transitory computer readable medium storing a program causing a computer to execute a method for correcting an output signal provided by a magnetoresistive sensor in the presence of an external magnetic field, the method comprising:
determining a deviation of the output signal from a linear response based on an amplitude of a high order component signal of an output voltage of the magnetoresistive sensor, wherein the amplitude of the high order component signal of the output voltage is representative of contributions to the output voltage by non-linear components, wherein the amplitude of the high order component signal of the output voltage increases with an increase in an applied magnetic field to the magnetoresistive sensor; and
determining a corrected output signal by compensating the output signal for the high order component signal such that the corrected output signal has a linearity error smaller than the linearity error of the output signal, wherein compensating the output signal includes adding an additional signal derived from the output signal and based on the amplitude of the high order component signal of the output voltage.

14. An integrated circuit (IC) configured to perform a method for correcting an output signal provided by a magnetoresistive sensor in the presence of an external magnetic field, the method comprising:
determining a deviation of the output signal from a linear response based on an amplitude of a high order component signal of an output voltage of the magnetoresistive sensor, wherein the amplitude of the high order component signal of the output voltage is representative of contributions to the output voltage by non-linear components, wherein the amplitude of the high order component signal of the output voltage increases with an increase in an applied magnetic field to the magnetoresistive sensor;
determining a corrected output signal by compensating the output signal for the high order component signal such that the corrected output signal has a linearity error smaller than the linearity error of the output signal, wherein compensating the output signal includes adding an additional signal derived from the output signal; and
determining a selected signal to output via at least one comparator disposed on the integrated circuit by:
comparing an output signal segment of the output signal and a segment transition threshold via the at least one comparator, wherein the integrated circuit is configured to output the output signal when the output signal segment is greater than a segment transistor threshold; and
comparing between a corrected output signal segment of the corrected output signal and the segment transistor threshold via the at least one comparator, wherein the integrated circuit is configured to output the corrected output signal when the corrected output signal segment is greater than the segment transistor threshold.

15. The integrated circuit (IC) according to claim 14,
wherein the output signal segment, the corrected output signal segment and the segment transition threshold comprise a voltage; and
the at least one comparator having inputs comprising: the output signal, the corrected output signal, and one of the segment transition threshold.

16. The integrated circuit (IC) according to claim 15, comprising a multiplexer configured to select one of the plurality of corrected output signal segments based on the output of at least one comparator.

17. The integrated circuit (IC) according to claim 14,
wherein the corrected voltage signal in each output signal segment is determined by: V_{corr, i}=Aᵢ+Bᵢ·V_{out i}, where V_{corr, i} is the corrected output signal segment, V_{out i} is the output signal segment, Ai and Bi are segment coefficients; and
wherein the at least one comparator is configured to select the segment coefficients Ai and Bi.

18. The integrated circuit (IC) according to claim 14,
wherein the output of at least one comparator is connected to a correction voltage generator circuit to generate a correction voltage, wherein the correction voltage generator circuit comprises one or more current mirrors and one or more resistors.

19. The integrated circuit (IC) according to claim 14, comprising:
a first voltage-to-current converter circuit is configured to generate a first current where;
the first current is a function of a difference between a sensor output voltage signal and a threshold signal when the sensor output voltage signal is greater than the threshold signal, and
the first current is zero when the sensor output voltage signal is lower than the threshold signal,
a correction resistor disposed between the sensor output voltage signal and the corrected output signal, generating the corrected output signal when first current is supplied to the correction resistor.

20. The integrated circuit (IC) according to claim 19, whereas the first current is a linear function of a difference between the sensor output voltage signal and the threshold signal when the sensor output voltage signal is greater than the threshold signal.

21. The integrated circuit (IC) according to claim 20, wherein the voltage-to-current converter circuit comprises an operational amplifier in which a first input voltage terminal is connected to a threshold signal and a second input terminal is connected to a first terminal of a transistor and the output of the operational amplifier directly drives a second terminal of the transistor and a third terminal of the transistor operate as a current output terminal of the voltage-to-current converter circuit.

22. The integrated circuit (IC) according to claim 20, wherein the voltage-to-current converter circuit comprises a MOS transistor.

23. An integrated circuit (IC), configured to perform a correction method provided by a magnetoresistive sensor in the presence of an external magnetic field, the method comprising:
determining a deviation of an output signal from a linear response based on an amplitude of a high order component signal of an output voltage of the magnetoresistive sensor, wherein the amplitude of the high order component signal of the output voltage is representative of contributions to the output voltage by non-linear components, wherein the amplitude of the high order component signal of the output voltage increases with an increase in an applied magnetic field to the magnetoresistive sensor;
determining a corrected output signal by compensating the output signal for the high order component signal such that the corrected output signal has a linearity error smaller than the linearity error of the output signal;
determining an additional signal such that the additional signal is close to or equal to a negative value of the high order component signal;
wherein said determining a corrected output signal comprises compensating the output signal for the high order component signal by adding the additional signal to the output signal; and
determining a selected signal to output via at least one comparator disposed on the IC by:
comparing an output signal segment of the output signal and a segment transition threshold via the at least one comparator, wherein the integrated circuit is configured to output the output signal when the output signal segment is greater than a segment transistor threshold; and
comparing between a corrected output signal component and the segment transistor threshold via the at least one comparator, wherein the integrated circuit is configured to output the corrected output signal when the corrected output signal segment is greater than the segment transistor threshold

24. The integrated circuit (IC) according to claim 23, wherein the additional signal is determined by at least one voltage multiplier.

25. The integrated circuit (IC) according to claim 24, further comprising at least a voltage amplifier such that the corrected output signal V_{corr} is V_{corr}=Vₒᵤₜ+(k/c₁³) Vₒᵤₜ³, where V_{corr} is the corrected output signal, Vₒᵤₜ is the output signal, α₁ is the first order coefficient, and k=C·α₃, α₃ is a third order coefficient, and C is a constant.

26. The integrated circuit (IC) according to claim 24 further comprising at least:
the comparator configured to receive the output signal and which output is used to trigger at least one multiplexer and/or one demultiplexer or any combination of both multiplexer and demultiplexer; and
at least one inverting amplifier configured to determine the additional signal determined by at least one voltage multiplier for each polarity of the output signal.

27. The integrated circuit (IC) according to claim 24, wherein a signal offset is added to the output signal and an input signal corresponding to the sum of the signal offset and the output signal is inputted to said at least one voltage multiplier.

28. The integrated circuit (IC) according to claim 23, comprising at least one Analog Multipurpose Unit (AMU) configured to determine the additional signal, wherein the AMU is configured to perform multiplication, division, and powers and root arithmetic.

29. The integrated circuit (IC) according to claim 28, wherein said at least one AMU is based, at least, on a LOG RATIO, a LOG and an ANTILOG operational amplifier configured to compute the input voltage to the power of n, n being a parameter defined by internal components of the AMU system.

30. The integrated circuit (IC) according to claim 28, further comprising at least: a comparator, a multiplexer and/or a demultiplexer or any combination of the multiplexer and/or demultiplexer, and at least one inverting amplifier, such that said at least one AMU determines the additional signal independently of a polarity of the output signal.

31. The integrated circuit (IC) according to claim 28,
further comprising a first voltage amplifier having a gain G1 and a second voltage amplifier having a gain G2;
wherein an offset signal is added to the output signal such that an input signal corresponding to the sum of the offset signal and the output signal is inputted into said at least two AMUs and into the first voltage amplifier;
such that the corrected output signal is the sum of the output voltage of the AMUs plus the output voltage of the first and second voltage amplifiers.

32. The integrated circuit (IC) according to claim 31, wherein one of the AMU is configured to compute the input signal to the power of two and wherein another AMU is configured to compute the input signal to the power of three.

33. The integrated circuit (IC) according to claim 23, comprising a digital system (DS) configured to determine digitally the additional signal from the output signal.

34. The integrated circuit (IC) according to claim 33, wherein the correction method is performed by the DS such that a digital corrected output signal is obtained as final output.

35. The integrated circuit (IC) according to claim 33, further comprising a digital-to-analog converter (DAC) configured to obtain from the digitally determined additional signal an analog additional signal, such that the corrected output signal is obtained by the addition of the output signal and the analog additional signal.

36. A characterization method to derive common parameters for a plurality of magnetoresistive sensors, wherein the common parameters are used when performing a correction method provided by a magnetoresistive sensor in the presence of an external magnetic field, the method comprising:
determining a deviation of the output signal from a linear response based on an amplitude of a high order component signal of an output voltage of the magnetoresistive sensor, wherein the amplitude of the high order component signal of the output voltage is representative of contributions to the output voltage by non-linear components, wherein the amplitude of the high order component signal of the output voltage increases with an increase in an applied magnetic field to the magnetoresistive sensor; and
determining a corrected output signal by compensating the output signal for the high order component signal such that the corrected output signal has a linearity error smaller than the linearity error of the output signal;
the method further comprising determining an additional signal such that the additional signal is close to or equal to a negative value of the high order component signal;
wherein said determining a corrected output signal comprises compensating the output signal for the high order component signal by adding the additional signal to the output signal.

37. The characterization method according to claim 36,
wherein the output signal Vₒᵤₜ is described by Vₒᵤₜ=a₀+a₁·H+Vₕₒ, where H is an external magnetic field, a₀ is an offset coefficient and a₁ is a first order coefficient, and wherein the high order component signal Vₕₒ is described by at least a third order coefficient a₃; and
wherein the correction method comprises determining an additional voltage signal corresponding to a negative value of the high order component voltage signal, and wherein determining a corrected output signal comprises compensating the output voltage signal being compensated for the high order component signal voltage by adding the additional voltage signal to the output signal voltage;
the characterization method comprising:
providing a plurality of magnetoresistive sensors and measuring the output signal for each magnetoresistive sensor;
determining the offset coefficient a₀, the first order coefficient a₁, and at least a third order coefficient a₃ by fitting the measured output signal to Vₒᵤₜ=a₀+a₁·H−a₃·H₃;
determining the approximated offset coefficient c₀ and the approximated first order coefficient c₁ by fitting the measured output signal to Vₒᵤₜ=c₀+c₁·H; and
determining median values for the determined offset coefficients a₀, first order coefficients a₁, at least third order coefficients a₃, approximated offset coefficients c₀ and approximated first order coefficients c₁.

38. The method according to claim 37, wherein said measuring the output signal is performed when submitting the magnetoresistive sensors to an external magnetic field corresponding to maximum operational magnetic field range of the magnetoresistive sensors.

39. The method according to claim 37, wherein said plurality of magnetoresistive sensors comprises a subset of magnetoresistive sensors comprised in a wafer.

40. The method according to claim 16,
wherein said measuring an output signal is performed when the magnetoresistive sensors are submitted to an external magnetic field corresponding to at least five different magnetic field magnitudes comprised between:
a high magnitude field corresponding to a maximum operational magnetic field range of the magnetoresistive sensor, and
a low magnitude field H₁ where the output signal (Vₒᵤₜ) follows a linear dependence within the magnetic field range (−H₁, H₁) described by: Vₒᵤₜ=a₀+a₁·H thereby enabling to determine offset a₀ and linear coefficient a₁ by a linear fit of Vₒᵤₜ and wherein the at least third order coefficients a₃ is derived by:
$${a}_{3} = \frac{[ ( {a}_{0} + {a}_{1} \cdot {H}_{2} ) - {V}_{{out}_{H2}} ]}{{H}_{2}^{3}} ,$$
where Vₒᵤₜ_{_{H2}} is the measured output voltage at the maximum operational magnetic field range H₂;
reconstructing the measured output signal Vₒᵤₜ=a₀+a₁ H−a₃·H³ from previously determined a₀, a₁ and a₃ coefficients for magnetic fields ranging from −H₂ to H₂ at any desired magnetic field step;
determining the approximated offset coefficient c₀ and the approximated first order coefficient c₁ by fitting the measured output signal to Vₒᵤₜ=c₀+c₁·H over the maximum operational magnetic field range; and
determining median values for the determined offset coefficients a₀, first order coefficients a₁, at least third order coefficients a₃, approximated offset coefficients c₀ and approximated first order coefficients c₁.
